(19) United States
(12) Patent Application Publication
(10) Pub. No.: US 2026/0068458 A1
(43) Pub. Date: Mar. 5, 2026

(54) DISPLAY DEVICE, METHOD OF MANUFACTURING THE SAME, AND ELECTRONIC DEVICE

(71) Applicant: SAMSUNG DISPLAY CO., LTD., YONGIN-SI (KR)

(72) Inventors: Ki Nyeng KANG, Yongin-si (KR); Sung Eun LEE, Yongin-si (KR); Bo Ik PARK, Yongin-si (KR); Keun Kyu SONG, Yongin-si (KR)

(21) Appl. No.: 19/265,252

(22) Filed: Jul. 10, 2025

(30) Foreign Application Priority Data
Sep. 2, 2024 (KR) 10-2024-0118731

(51) Int. Cl. H10K 59/131; H10K 59/12; H10K 59/122

(52) U.S. Cl. CPC H10K 59/131; H10K 59/1201; H10K 59/122

(57) ABSTRACT

A display device including: a pixel circuit layer; a via layer disposed on the pixel circuit layer, wherein the via layer includes a trench; a first via hole and a second via hole passing through the via layer; a first metal layer electrically connected to the pixel circuit layer through the first via hole; an anode electrode disposed on the via layer; a first emission component disposed on the anode electrode; a charge generation layer disposed on the first emission component; and a second emission component disposed on the charge generation layer, wherein the pixel circuit layer includes: a transistor electrically connected to an initialization voltage node, wherein the initialization voltage node is configured to transmit an initialization voltage, and wherein the transistor is electrically connected to the charge generation layer through the first metal layer.

### CROSS-REFERENCE TO RELATED APPLICATION

The present application claims priority under 35 U.S.C. § 119 to Korean patent application number 10-2024-0118731 filed on Sep. 2, 2024, the disclosure of which is incorporated by reference herein in its entirety.

### TECHNICAL FIELD

Various embodiments of the present disclosure relate to a display device, a method of manufacturing the display device, and an electronic device.

### DESCRIPTION OF RELATED ART

With advancements in information technology, display devices have become increasingly important as a medium for connecting users with information. Consequently, the use of various types of display devices, such as liquid crystal display devices and organic light-emitting diode display devices, has grown significantly.

### SUMMARY

An aspect of the present disclosure pertains to a display device, an electronic device, and a method for manufacturing the display device, designed to minimize leakage current between adjacent sub-pixels.

However, objects of the present disclosure are not limited to those described above, and various modifications can be made without departing from the spirit and scope of the present disclosure.

An embodiment of the present disclosure provides a display device including: a pixel circuit layer; a via layer disposed on the pixel circuit layer, wherein the via layer includes a trench; a first via hole and a second via hole passing through the via layer; a first metal layer electrically connected to the pixel circuit layer through the first via hole; an anode electrode disposed on the via layer; a first emission component disposed on the anode electrode; a charge generation layer disposed on the first emission component; and a second emission component disposed on the charge generation layer, wherein the pixel circuit layer includes: a transistor electrically connected to an initialization voltage node, wherein the initialization voltage node is configured to transmit an initialization voltage, and wherein the transistor is electrically connected to the charge generation layer through the first metal layer.

The display device further including a partition wall disposed on the first metal layer, wherein the partition wall includes: a first partition wall layer; and a second partition wall layer disposed on the first partition wall layer, wherein the second partition wall layer is wider in a direction parallel to a surface of the substrate than the first partition wall layer.

The trench includes a first trench and a second trench, and wherein a height of the first trench is less than a height of the second trench.

The display device further includes: a second metal layer electrically connected to the pixel circuit layer through the second via hole; and a cathode electrode disposed on the second emission component, wherein the second metal layer is in contact with the cathode electrode in an area adjacent to or overlapping the second trench.

The first metal layer and the second metal layer are disposed on an identical plane, wherein the first partition wall is in contact with the first metal layer, and wherein an upper surface of each of the first emission component, the charge generation layer, and the second emission component has a stepped portion.

The first metal layer is in contact with the charge generation layer in an area adjacent to or overlapping the first trench.

The charge generation layer is not in contact with the second metal layer.

The first metal layer is in contact with the charge generation layer in a first contact area, and wherein, in a plan view, the first contact area is spaced apart from the anode electrode, and encloses at least a portion of a periphery of the anode electrode.

The display device further includes: a second metal layer electrically connected to the pixel circuit layer through the second via hole; and a cathode electrode disposed on the second emission component, wherein the cathode electrode is in contact with the second metal layer in a second contact area, and wherein, in a plan view, the second contact area encloses at least a portion of the periphery of the anode electrode.

The first metal layer is a single layer including titanium (Ti), or multiple layers including at least one of titanium (Ti), aluminum (Al), copper (Cu), and molybdenum titanium (MoTi).

A side surface of the anode electrode is forward-tapered.

The display device further includes a display area where pixels are disposed, wherein the display device is a hole in active area (HIAA) display device, and a hole is formed in the display area.

The display device further includes a first sub-pixel and a second sub-pixel, wherein the charge generation layer is not electrically connected between the first sub-pixel and the second sub-pixel.

The first metal layer is electrically connected to the pixel circuit layer through the second via hole, wherein the first metal layer is in contact with the charge generation layer in a contact area, and wherein, in a plan view, the contact area encloses a first portion of a periphery of the anode electrode, and does not enclose a second portion of the periphery of the anode electrode.

An embodiment of the present disclosure provides a method of manufacturing a display device including: forming a pixel circuit layer including a transistor; forming a via layer on the pixel circuit layer; forming a first via hole and a second via hole in the via layer; forming a first metal layer; forming a trench by etching the via layer; forming an anode electrode on the via layer; and forming an emission structure on the anode electrode, wherein forming the emission structure includes: forming a first emission component on the anode electrode; forming a charge generation layer on the first emission component; and forming a second emission component on the charge generation layer, wherein the transistor comprises an initialization transistor electrically connected to an initialization voltage node, wherein the initialization voltage node is configured to transmit an initialization voltage, wherein forming the charge generation layer comprises contacting the charge generation layer with the first metal layer, and wherein the charge generation layer is electrically connected to the initialization transistor.

The method further includes forming a partition wall on the first metal layer, wherein forming the partition wall includes: forming a first partition wall layer; and forming a second partition wall layer on the first partition wall layer, and wherein the second partition wall layer is wider the first partition wall layer.

Forming the trench includes forming a first trench and a second trench, and wherein forming the first trench and the second trench includes etching the via layer such that a height of the first trench is less than a height of the second trench.

The method further includes: forming a second metal layer; and forming a cathode electrode on the second emission component, wherein the second metal layer is electrically connected to the pixel circuit layer through the second via hole, wherein the first metal layer and the second metal layer are formed in an identical process, wherein forming the cathode electrode includes contacting the cathode electrode with the second metal layer, and wherein the second metal layer is electrically connected to a line configured to supply a cathode voltage.

Each of the first metal layer and the second metal layer is a single layer including titanium (Ti), or multiple layers including at least one of titanium (Ti), aluminum (Al), copper (Cu), and molybdenum titanium (MoTi), and wherein the anode electrode has a forward-tapered side surface.

The first metal layer is electrically connected to the pixel circuit layer through the second via hole, and wherein, in a plan view, an area where the charge generation layer is in contact with the first metal layer encloses at least a portion of a periphery of the anode electrode.

An embodiment of the present disclosure provides an electronic device including: a processor configured to provide input image data; and a display device configured to display an image based on the input image data, wherein the display device includes: a pixel circuit layer; a via layer disposed on the pixel circuit layer, wherein the via layer includes a trench; a first via hole and a second via hole passing through the via layer; a first metal layer electrically connected to the pixel circuit layer through the first via hole; an anode electrode disposed on the via layer; a first emission component disposed on the anode electrode; a charge generation layer disposed on the first emission component; and a second emission component disposed on the charge generation layer, wherein the pixel circuit layer includes: a transistor electrically connected to an initialization voltage node, wherein the initialization voltage node is configured to transmit an initialization voltage, and wherein the transistor is electrically connected to the charge generation layer through the first metal layer.

An embodiment of the present disclosure provides a display device including: a pixel circuit layer; a via layer disposed on the pixel circuit layer and including a trench; a via extending through the via layer; a conductive layer electrically connected to the pixel circuit layer through the via; an anode disposed on the via layer; an emission component disposed on the anode; and a charge generation layer disposed on the emission component, wherein the pixel circuit layer includes: a transistor configured to provide an initialization voltage, and wherein the transistor is electrically connected to the charge generation layer through the conductive layer.

### BRIEF DESCRIPTION OF THE DRAWINGS

FIG. 1 is a block diagram illustrating a display device according to an embodiment of the present disclosure.

FIG. 2 is a block diagram illustrating an example of any one of sub-pixels of FIG. 1.

FIG. 3 is a circuit diagram illustrating an example of the sub-pixel of FIG. 2.

FIG. 4 is a plan view illustrating an example of a display panel of FIG. 1.

FIG. 5 is an exploded perspective view illustrating a portion of the display panel of FIG. 4.

FIG. 6 is a plan view illustrating an example of any one of pixels of FIG. 5.

FIG. 7 is a sectional view taken along line I-I′ of FIG. 6 in accordance with an embodiment of the present disclosure.

FIG. 8 is a sectional view illustrating an emission structure of FIG. 7.

FIG. 9 is a sectional view illustrating an enlargement of area A of FIG. 7.

FIG. 10 is a plan view for explaining a contact area in accordance with an embodiment of the present disclosure.

FIG. 11 is a sectional view of a display panel in accordance with another embodiment of the present disclosure.

FIG. 12 is a plan view for explaining a contact area in accordance with another embodiment of the present disclosure.

FIG. 13 is a flowchart illustrating a method of manufacturing the display device in accordance with an embodiment of the present disclosure.

FIGS. 14, 15, 16, 17 and 18 are schematic sectional views illustrating a method of manufacturing the display device in accordance with an embodiment of the present disclosure.

FIG. 19 is a schematic sectional view illustrating a method of manufacturing the display device in accordance with an embodiment of the present disclosure.

FIG. 20 is a schematic block diagram illustrating an electronic device including a display device in accordance with an embodiment of the present disclosure.

FIG. 21 is a schematic diagram illustrating an example where the electronic device of FIG. 20 is a smartphone.

FIG. 22 is a schematic diagram illustrating an example where the electronic device of FIG. 20 is a tablet computer.

### DETAILED DESCRIPTION OF THE EMBODIMENTS

Hereinafter, embodiments of the present disclosure will be described in detail with reference to the attached drawings. For clarity, components necessary for understanding of the operations according to the present disclosure will be described, while other components are omitted to avoid obscuring the gist of the disclosure. Accordingly, the present disclosure is not limited to the embodiments set forth herein and may be implemented in various other forms. These embodiments are provided to ensure a thorough and complete understanding of the present disclosure and to fully convey its technical spirit to those skilled in the art.

It will be understood that when an element is referred to as being “coupled” or “connected” to another element, it can be directly coupled or connected to the other element or intervening elements may be present therebetween. The terminology used herein is for the purpose of describing particular embodiments and is not intended to be limiting. In the specification, when an element is referred to as “comprising” or “including” a component, it does not preclude another component but may further include other components unless the context clearly indicates otherwise. The phrases “at least one of X, Y, and Z” and “at least one selected from the group consisting of X, Y, and Z” should be understood to encompass X only, Y only, Z only, or any combination of two or more of X, Y, and Z (e.g., XYZ, XYY, YZ, and ZZ). As used herein, the term “and/or” can include any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element.

Spatially relative terms, such as “beneath,” “below,” “under,” “lower,” “above,” “upper,” “over,” “higher,” “side” (e.g., as in “sidewall”), and the like are used herein for descriptive purposes to indicate the relationship of one element or feature to another, as shown in the drawings. These terms are intended to encompass different orientations of an apparatus in use, operation, and/or manufacture, in addition to the orientation depicted in the drawings. For example, if the apparatus shown in the drawings is turned upside down, elements described as “below” or “beneath” other elements or features would then be oriented “above” the other elements or features. Thus, the term “below” can encompass both an orientation of above and below. Furthermore, the apparatus may be positioned differently (e.g., rotated 90 degrees or at other orientations), and the spatially relative terms should be interpreted accordingly.

The various embodiments described herein are present with reference to drawings that are schematic illustrations of idealized embodiments. Variations in the shapes depicted in the illustrations, due to factors such as manufacturing techniques and/or tolerances, are to be expected. Therefore, the embodiments disclosed herein should not be construed as limited to the particular illustrated shapes of regions, but are to include deviations in shapes that result from, for instance, manufacturing. The shapes illustrated in the drawings are not intended to represent the actual shapes of the device's regions and should not be considered limiting.

The present disclosure relates to a display device, a method of manufacturing the device, and an electronic device that incorporates it, designed to reduce leakage currents between adjacent sub-pixels. The display structure includes a pixel circuit layer, a via layer with trenches and via holes, and emission components such as an anode electrode, a charge generation layer, and a cathode electrode. Key features involve the innovative arrangement of a charge generation layer CGL to connect with an initialization voltage node via transistors, ensuring precise voltage control to prevent operational defects like “black spot phenomena.” The trench and via design plays a crucial role in optimizing electrical connections while minimizing lateral leakage.

The present disclosure emphasizes a layered structure, including metal layers for enhanced conductivity and partition walls for structural and optical separation between sub-pixels. The emission components, arranged in tandem, enhance light generation and output efficiency while ensuring electrical isolation. This design is particularly suited for integration into high-density displays such as OLEDs for smartphones and other compact electronic devices, where leakage control is critical for performance and reliability. Variations in the design allow flexibility in implementation while maintaining core functionality.

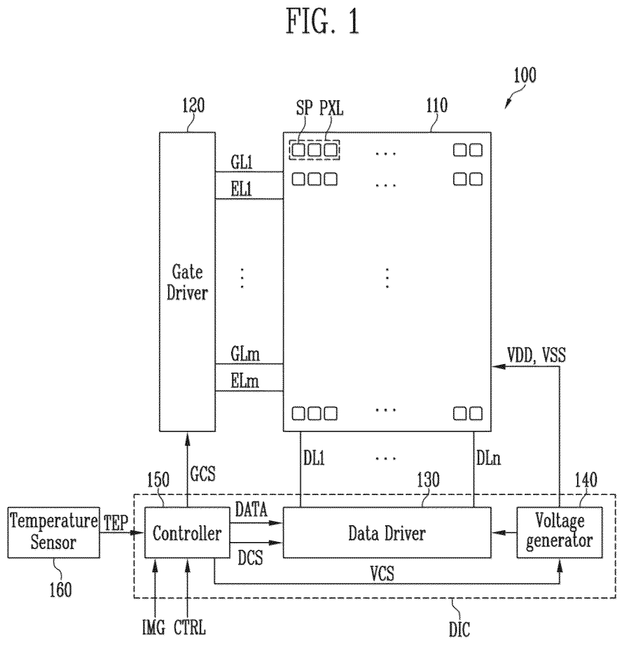

FIG. 1 is a block diagram illustrating a display device 100 according to an embodiment of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light in a specific color such as red, green, blue, cyan, magenta, or yellow. Two or more sub-pixels among the sub-pixels SP may form one pixel PXL. For example, as illustrated in FIG. 1, three sub-pixels may form one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal that initiates each frame, a horizontal synchronization signal for coordinating the output of gate signals with the timing of a data signal application, and the like.

In embodiments, there may be further provided first to m-th emission control lines EL1 to ELm connected to the sub-pixels SP in the row direction. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, embodiments are not limited to the aforementioned example. For example, the gate driver 120 may be divided into two or more drivers that are physically and/or logically distinguished from each other. The drivers may be disposed on a first side of the display panel 110 and a second side of the display panel 110 opposite to the first side. As such, the gate driver 120 may be disposed around the display panel 110 in various configurations, depending on the embodiment.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLm. Hence, the associated sub-pixels SP may generate light corresponding to the data signals. As a result, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 is configured to generate a plurality of voltages and provide the generated voltages to components of the display device 100. For example, the voltage generator 140 may be configured to receive an input voltage from an external device provided outside the display device 100, adjust the received voltage, and regulate the adjusted voltage, thus generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. In other embodiments, the first power voltage VDD or the second power voltage VSS may be provided by an external device provided outside the display device 100.

In addition, the voltage generator 140 may generate various voltages. For example, the voltage generator 140 may generate an initialization voltage to be applied to the sub-pixels SP. For example, during a sensing operation to measure the electrical characteristics of transistors and/or light emitting elements of the sub-pixels SP, a specific reference voltage may be applied to each of the first to n-th data lines DL1 to DLn. The voltage generator 140 may generate the reference voltage.

The controller 150 may control overall operations of the display device 100. The controller 150 may receive input image data IMG and a control signal CTRL from an external device to manage the operation of displaying the input image data IMG. The controller 150 may generate the gate control signal GCS, the data control signal DCS, and the voltage control signal VCS, in response to the control signal CTRL.

The controller 150 may convert the input image data IMG to make it compatible with the display device 100 or the display panel 110 and then output image data DATA. In embodiments, the controller 150 may align the input image data IMG on a row-by-row base to match the arrangement of the sub-pixels SP before outputting the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. In other embodiments, at least one of the data driver 130, the voltage generator 140, and the controller 150 may be provided as a component separated from the driver integrated circuit DIC.

The display device 100 may include at least one temperature sensor 160. The temperature sensor 160 is configured to sense a peripheral temperature and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of an image output from the display panel 110 in response to the temperature data TEP. For example, the controller 150 may control components such as the data driver 130 and/or the voltage generator 140, thereby adjusting data signals as well as the first and second power voltages VDD and VSS.

The display device 100 in accordance with an embodiment may be a device configured to display a video (e.g., moving) or a static image. The display device 100 may be used not only as portable electronic devices such as a mobile phone, a smart phone, a tablet personal computer, a smart watch, and a watch phone, but also as display screens of various products such as a television, a notebook, a monitor, an advertisement panel, and an internet of tings (IOT) device. In this disclosure, the application field of the display device 100 is not limited to a specific example.

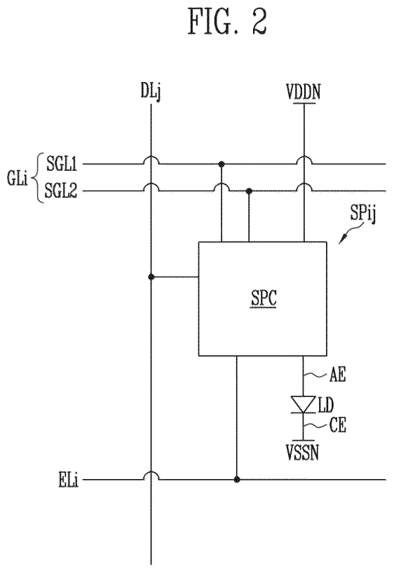

FIG. 2 is a block diagram illustrating an example of any one of the sub-pixels SP of FIG. 1. In FIG. 2, a sub-pixel SPij is illustrated, the sub-pixel SPij being disposed on an i-th row (where i is an integer equal to or greater than 1 and less than or equal to m) and a j-th column (where j is an integer equal to or greater than 1 and less than or equal to n) among the sub-pixels SP of FIG. 1.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN may serve as a node for transmitting the first power voltage VDD of FIG. 1. The second power voltage node VSSN may serve as a node for transmitting the second power voltage VSS of FIG. 1.

An anode electrode AE of the light emitting element LD may be connected to the first power voltage node VDDN through the sub-pixel circuit SPC. A cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD in response to signals received through these signal lines.

The sub-pixel circuit SPC may operate in response to a gate signal received through the i-th gate line GLi. The i-th gate line GLi may include one or more sub-gate lines. In embodiments, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. Accordingly, if the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. In the case where the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of gate signals received through the first and second sub-gate lines SGL1 and SGL2. The sub-pixel circuit SPC may regulate the current flowing from the first power voltage node VDDN to the second power voltage node VSSN through the light emitting element LD based on the stored voltage, in response to an emission control signal received via the i-th emission control line ELi. Therefore, the light emitting element LD may generate light with a luminance corresponding to the data signal.

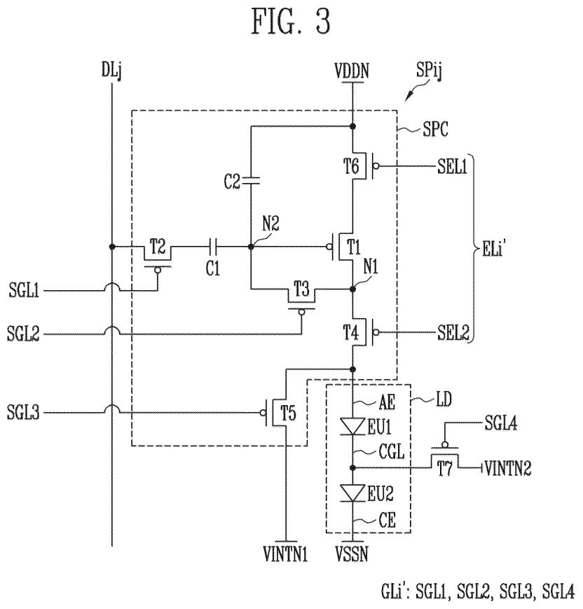

FIG. 3 is a circuit diagram illustrating an example of the sub-pixel SPij of FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and a j-th data line DLj. Compared to the i-th gate line GLi of FIG. 2, the i-th gate line GLi′ may further include a third sub-gate line SGL3 and a fourth sub-gate line SGL4. Compared to the i-th emission control line ELi of FIG. 2, the i-emission control line ELi′ may include a first sub-emission control line SEL1 and a second sub-emission control line SEL2.

The sub-pixel circuit SPC may include first to seventh transistors T1 to T7, and first and second capacitors C1 and C2.

The first transistor T1 is connected between a first power voltage node VDDN and a first node N1. A gate of the first transistor T1 may be connected to a second node N2. Hence, the first transistor T1 may be turned on based on the voltage level of the second node N2. The first transistor T1 may be referred to as a driving transistor.

The second transistor T2 may be connected between the j-th data line DLj and the second node N2. A gate of the second transistor T2 may be connected to a first sub-gate line SGL1. Hence, the second transistor T2 may be turned on in response to a gate signal of the first sub-gate line SGL1. The second transistor T2 may be referred to as a switching transistor.

The third transistors T3 may be connected between the first node N1 and the second node N2. A gate of the third transistor T3 may be connected to a second sub-gate line SGL2. Hence, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2. Hence, the fourth transistor T4 may be turned on in response to an emission control signal of the second sub-emission control line SEL2.

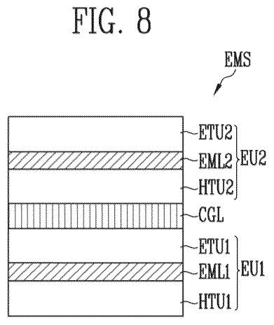

The fifth transistor T5 (e.g., referred also to as a first initialization transistor) may be connected between the anode electrode AE of the light emitting element LD and a first initialization voltage node VINTN1. For example, the fifth transistor T5 may be electrically connected to a first emission component EU1 (refer to FIG. 8) that forms the light emitting element LD, and may transmit a first initialization voltage to the first emission component EU1. The first initialization voltage node VINTN1 is configured to transmit the first initialization voltage. In embodiments, the first initialization voltage may be provided by the voltage generator 140 of FIG. 1. In other embodiments, the first initialization voltage may be provided by an external device outside the display device 100. A gate of the fifth transistor T5 may be connected to the third sub-gate line SGL3. Hence, the fifth transistor T5 may be turned on in response to a gate signal of the third sub-gate line SGL3.

The sixth transistor T6 is connected between the first power voltage node VDDN and the first transistor T1. A gate of the sixth transistor T6 may be connected to the first sub-emission control line SEL1. Hence, the sixth transistor T6 may be turned on in response to an emission control signal of the first sub-emission control line SEL1.

The seventh transistor T7 (e.g., referred also to as a second initialization transistor) may be connected between a charge generation layer CGL of the light emitting element LD and a second initialization voltage node VINTN2. For example, the seventh transistor T7 may be electrically connected to the charge generation layer CGL (refer to FIG. 8) that forms the light emitting element LD, and may transmit a second initialization voltage to a second emission component EU2 (refer to FIG. 8). The second initialization voltage node VINTN2 is configured to transmit the second initialization voltage. In embodiments, the second initialization voltage may be provided by the voltage generator 140 of FIG. 1. In other embodiments, the second initialization voltage may be provided by an external device outside the display device 100. A gate of the seventh transistor T7 may be connected to the fourth sub-gate line SGL4. Hence, the seventh transistor T7 may be turned on in response to a gate signal of the fourth sub-gate line SGL4.

In an embodiment, the second initialization voltage may be the same as the first initialization voltage. However, the present disclosure is not limited to the aforementioned example, and the second initialization voltage may be different from the first initialization voltage depending on characteristics of the first and second emission components EU1 and EU2. In an embodiment, a signal for supplying the first initialization voltage and a signal for supplying second initialization voltage may be applied at the same time. However, the present disclosure is not limited to this example, and the signal for supplying the first initialization voltage and the signal for supplying second initialization voltage may be applied at different timings.

The first capacitor C1 is connected between the second transistor T2 and the second node N2. The second capacitor C2 is connected between the first power voltage node VDDN and the second node N2.

As described, the sub-pixel circuit SPC may include the first to seventh transistors T1 to T7 and the first and second capacitors C1 and C2. However, embodiments are not limited to the above. The sub-pixel circuit SPC may be implemented in various forms, each including a plurality of transistors and one or more capacitors. Depending on the specific implementation of the sub-pixel circuit SPC, the number of sub-gate lines included in the i-th gate line GLi′ and the number of sub-emission control lines included in the i-th emission control line ELi′ may vary.

The first to seventh transistors T1 to T7 may be formed of P-type transistors. Each of the first to seventh transistors T1 to T7 may be formed of a metal oxide silicon field effect transistor (MOSFET). However, embodiments are not limited to the above. For example, at least one of the first to seventh transistors T1 to T7 may be replaced with an N-type transistor.

In embodiments, the first to seventh transistors T1 to T7 may include an amorphous silicon semiconductor, a monocrystalline silicon semiconductor, a polycrystalline silicon semiconductor, an oxide semiconductor, or the like.

The light emitting element LD may include the anode electrode AE, a cathode electrode CE, and an emission layer {or an emission structure (refer to FIG. 8)}. The emission layer may be disposed between the anode electrode AE and the cathode electrode CE. When the emission control signals of the first and second sub-emission control lines SEL1 and SEL2 are set to a low level after the data signal transmitted through the j-th data line DLj influences the voltage at the second node N2, the fourth and sixth transistors T4 and T6 may turn on. The first transistor T1 may also turn on depending on the voltage at the second node N2, allowing current to flow from the first power voltage node VDDN to the second power voltage node VSSN. Consequently, the light-emitting element LD may emit light proportional to the amount of current.

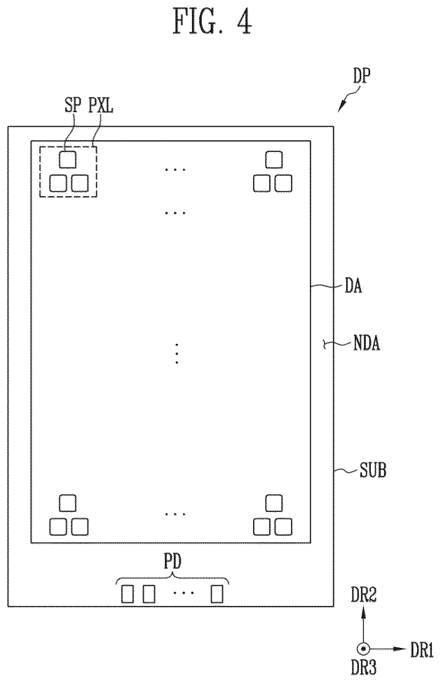

FIG. 4 is a plan view illustrating an example of the display panel 110 of FIG. 1.

Referring to FIG. 4, an example DP of the display panel 110 depicted in FIG. 1 may include a display area DA and a non-display area NDA. The display panel DP may display an image through the display area DA. The non-display area NDA may be disposed around the display area DA.

In an embodiment, the display panel DP may be a Hole-In-Active-Area (HIAA) display panel, where a hole (e.g., a hole accommodating a camera or overlapping with a camera) is formed in the display area DA. For example, the display device 100 in accordance with an embodiment may be an HIAA display device. However, the present disclosure is not limited to the aforementioned example.

The display panel DP may include a substrate SUB, sub-pixels SP, and pads PD.

When the display panel DP is used as a display screen for a head-mounted display (HMD), a virtual reality (VR) device, a mixed reality (MR) device, an augmented reality (AR) device, and the like, the display panel DP may be positioned very close to the user's eyes. In such cases, relatively high-density sub-pixels SP may be required. To achieve this increased pixel density, the substrate SUB may be implemented using a silicon substrate. The sub-pixels SP and/or the display panel DP may be formed on the substrate SUB that is a silicon substrate. The display device 100 (refer to FIG. 1) including the display panel DP formed on the substrate SUB that is a silicon substrate may be referred to as an OLED on Silicon (OLEDoS) display device.

The sub-pixels SP may be disposed in the display area DA on the substrate SUB. The sub-pixels SP may be arranged in the form of a matrix along a first direction DR1 and a second direction DR2 intersecting with the first direction DR1. However, embodiments are not limited to the aforementioned example. For example, the sub-pixels SP may be arranged in a zigzag pattern in the first direction DR1 and the second direction DR2. For example, the sub-pixels SP may be arranged in a pentile form. The first direction DR1 may refer to a row direction, and the second direction DR2 may refer to a column direction.

Two or more sub-pixels among the sub-pixels SP may form one pixel PXL.

Components for controlling the sub-pixels SP may be disposed in the non-display area NDA on the substrate SUB. For example, lines such as the first to m-th gate lines GL1 to GLm and the first to n-th data lines DL1 to DLn shown in FIG. 1, which are connected to the sub-pixels SP, may be arranged in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and positioned in the non-display area NDA. In other embodiments, the gate driver 120 may be implemented as an integrated circuit separate from the display panel DP. In embodiments, the temperature sensor 160 may be positioned in the non-display area NDA to sense the temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP with other components of the display device 100 (refer to FIG. 1). In embodiments, voltages and signals required for the operation of the components included in the display panel DP may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be supplied from the driver integrated circuit DIC through the pads PD. Additionally, when the gate driver 120 is mounted on the display panel DP, the gate control signal GCS may be transmitted from the driver integrated circuit DIC to the gate driver 120 through the pads PD.

In embodiments, a circuit board may be electrically connected to the pads PD by a conductive adhesive component such as an anisotropic conductive film. Here, the circuit board may be a flexible circuit board (FPCB) or flexible film that is made of flexible material. The driver integrated circuit DIC may be mounted on the circuit board and be electrically connected to the pads PD.

In embodiments, the display area DA may have various shapes. The display area DA may have a closed-loop shape, including linear and/or curved sides. For example, the display area DA may have shapes such as a polygon, a circle, a semicircle, and an ellipse.

In embodiments, the display panel DP may have a planar display surface. In other embodiments, the display panel DP may have a display surface that is at least partially rounded. In embodiments, the display panel DP is bendable, foldable, or rollable. In the aforementioned cases, the display panel DP and/or the substrate SUB may include materials having flexible properties.

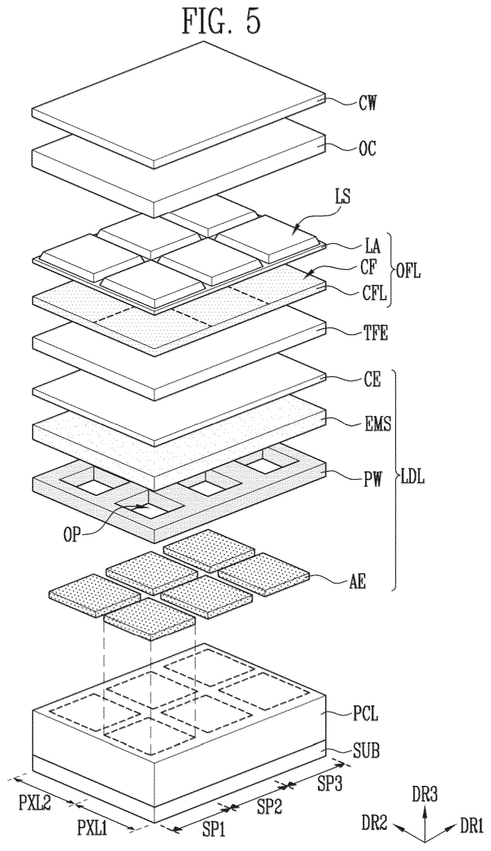

FIG. 5 is an exploded perspective view illustrating a portion of the display panel DP of FIG. 4. For clarity and simplicity, FIG. 5 schematically depicts a portion of the display panel DP corresponding to two pixels PXL1 and PXL2 among the pixels PXL of FIG. 4. The remaining portions of the display panel DP corresponding to the other pixels may be configured in a similar manner.

Referring to FIGS. 4 and 5, each of the first and second pixels PXL1 and PXL2 may include first to third sub-pixels SP1, SP2, and SP3. However, embodiments are not limited to the aforementioned example. For example, each of the first and second pixels PXL1 and PXL2 may include four sub-pixels, or may include two sub-pixels.

In FIG. 5 there is illustrated the case where the first to third sub-pixels SP1, SP2, and SP3 have rectangular shapes and the same size when viewed in a third direction DR3 intersecting with the first and second directions DR1 and DR2. However, embodiments are not limited to the aforementioned example. The first to third sub-pixels SP1, SP2, and SP3 may have various shapes.

The display panel DP may include a substrate SUB, a pixel circuit layer PCL, a light-emitting-element layer LDL, an encapsulation layer TFE, an optical functional layer OFL, an overcoat layer OC, and a cover window CW.

In embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In embodiments, the substrate SUB may include a glass substrate. In other embodiments, the substrate SUB may include a polyimide (PI) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least some of the circuit components, lines, or the like. The conductive patterns may include copper, but embodiments are not limited thereto.

The circuit elements may include respective sub-pixel circuits SPC (refer to FIG. 2) of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. Hereinafter, the term “overlapping” may mean “overlapping when viewed in a plane,” where the plane refers to the surface on which the substrate SUB is provided. In embodiments, when the substrate SUB is formed of a silicon substrate, the semiconductor portion may be included in the substrate SUB, and the gate electrode may be included in the pixel circuit layer PCL as a conductive pattern of the pixel circuit layer PCL. In an embodiment, when the substrate SUB is formed of a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane formed in the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, and a data line. The lines may further include a line connected to the first power voltage node VDDN of FIG. 2. Furthermore, the lines may further include a line connected to the second power voltage node VSSN of FIG. 2.

The light-emitting-element layer LDL may include anode electrodes AE, a partition wall PW, an emission structure EMS, and a cathode electrode CE.

The anode electrodes AE may be disposed on the pixel circuit layer PCL. The anode electrodes AE may contact circuit elements of the pixel circuit layer PCL. The anode electrodes AE may include opaque conductive material capable of reflecting light, but embodiments are not limited thereto.

The partition wall PW may be disposed on the pixel circuit layer PCL. The partition wall PW may enclose the anode electrodes AE. The partition wall PW may correspond to a pixel defining layer, which defines emission areas corresponding to the first to third sub-pixels SP1 to SP3, respectively. The partition wall PW may include openings OP overlapping areas where the anode electrodes AE can be disposed. For example, the anode electrodes AE may be disposed in the openings OP defined by the partition wall PW. Respective emission areas corresponding to the first to third sub-pixels SP1 to SP3 may be defined according to the openings OP in the partition wall PW. In an area adjacent to a boundary of neighboring sub-pixels, the partition wall PW may create a discontinuity in the emission structure EMS.

In embodiments, the partition wall PW may include inorganic material. In this case, the partition wall PW may include a plurality of inorganic layers stacked on top of one another. For example, the partition wall PW may include silicon oxide (SiOₓ) and silicon nitride (SiNₓ).

The emission structure EMS may be disposed on the anode electrodes AE. The emission structure EMS may include an emission layer configured to generate light, an electron transport layer configured to transport electrons, and a hole transport layer configured to transport holes.

In embodiments, the emission structure EMS may fill the openings OP in the partition wall PW, and may also be disposed on an upper portion of the partition wall PW. In other words, at least a portion of the emission structure EMS may fill each of the openings OP in the partition wall PW and may be interrupted at the boundaries of the area where the partition wall PW is defined (e.g., at the boundaries between the partition wall PW and its openings OP). For instance, the portions of the emission structure EMS corresponding to the first to third sub-pixels SP1 to SP3 may be separated from each other, with each portion positioned with the corresponding opening OP in the partition wall PW. However, embodiments are not limited to the aforementioned example.

The cathode electrode CE may be disposed on the emission structure EMS. In an embodiment, the cathode electrode CE may extend across the first to third sub-pixels SP1 to SP3. In this case, the cathode electrode CE may be a common electrode for the first to third sub-pixels SP1 to SP3. Alternatively, in an embodiment, the cathode electrode CE may fill the openings OP of the partition wall PW and be interrupted at the boundaries between the partition wall PW and its openings OP. In this case, the cathode electrode CE may be individually provided for each of the first to third sub-pixels SP1 to SP3.

The cathode electrode CE may be a thin-film metal layer having a thickness allowing light emitted from the emission structure EMS to pass therethrough. The cathode electrode CE may be made of a metal material having a relatively small thickness, or a transparent conductive material. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and a compound thereof. However, the material of the cathode electrode CE is not limited to the foregoing example.

Any one of the anode electrodes AE, a portion of the emission structure EMS that overlaps the any one anode electrode AE, and a portion of the cathode electrode CE that overlaps the portion of the emission structure EMS can be understood as constituting one light emitting element LD (refer to FIG. 2). In other words, each of the light emitting elements LD of the first to third sub-pixels SP1 to SP3 may include one anode electrode AE, a portion of the emission structure EMS that overlaps the one anode electrode AE, and a portion of the cathode electrode CE that overlaps the portion of the emission structure EMS. In each of the first to third sub-pixels SP1 to SP3, holes injected from the anode electrode AE and electrons injected from the cathode electrode CE are transported into the emission layer of the emission structure EMS, where they form excitons. As the excitons transition from an excited state to a ground state, light is generated. The luminance of the emitted light is determined by the amount of current flowing through the emission layer, while the wavelength range of the light depends on the configuration of the emission layer.

The encapsulation layer TFE may be disposed on the cathode electrode CE. The encapsulation layer TFE may cover the light-emitting-element layer LDL and/or the pixel circuit layer PCL. The encapsulation layer TFE may be configured to prevent oxygen and/or water or the like from penetrating into the light-emitting-element layer LDL. In embodiments, the encapsulation layer TFE may include a structure formed by alternately stacking one or more inorganic layers and one or more organic layers. For example, the inorganic layer may include silicon nitride, silicon oxide, silicon oxynitride (SiOₓNy), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the encapsulation layer TFE are limited to the aforementioned examples.

The encapsulation layer TFE may further include a thin film, including aluminum oxide (AlOₓ), to enhance the encapsulation efficiency of the encapsulation layer TFE. The thin film including aluminum oxide may be positioned on an upper surface of the encapsulation layer TFE that faces the optical functional layer OFL and/or under a lower surface of the encapsulation layer TFE that faces the light-emitting-element layer LDL.

The thin film including aluminum oxide may be formed through an atomic layer deposition (ALD) method. However, embodiments are not limited to the aforementioned example. The encapsulation layer TFE may further include a thin film formed of at least one of various materials suitable for enhancing the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the emission structure EMS and selectively output light in a wavelength range or color corresponding to each sub-pixel. The color filter layer CFL may include color filters CF respectively corresponding to the first to third sub-pixels SP1 to SP3. Each of the color filters CF allows light within a wavelength range corresponding to the related sub-pixel to pass therethrough. For example, the color filter CF that corresponds to the first sub-pixel SP1 allows light in a red color to pass therethrough, the color filter CF that corresponds to the second sub-pixel SP2 allows light in a green color to pass therethrough, and the color filter CF that corresponds to the third sub-pixel SP3 allows light in a blue color to pass therethrough. Depending on the light emitted from the emission structure EMS of each sub-pixel, it may be possible to omit at least some of the color filters CF.

The lens array LA may be disposed on the color filter layer CFL. The lens array LA may include lenses LS that respectively correspond to the first to third sub-pixels SP1 to SP3. Each of the lenses LS may output and direct light emitted from the emission structure EMS along a designated path, thereby improving light output efficiency. The lens array LA may have a relatively high refractive index. For example, the lens array LA may have a higher refractive index than the overcoat layer OC. In embodiments, the lenses LS may include organic material. In embodiments, the lenses LS may include acrylic material. However, the material of the lenses LS is not limited to the foregoing example.

In embodiments, at least some of the color filters CF of the color filter layer CFL and at least some of the lenses LS of the lens array LA, relative to the openings OP in the partition wall PA, in a direction parallel to the plane defined by the first and second directions DR1 and DR2. Specifically, in a central area of the display area DA, the center of each color filter CF and the center of each lens LS may be aligned or overlapped with the center of its corresponding opening OP in the partition wall PW. For example, in the central area of the display area DA, each opening OP of the partition wall PW may completely overlap its corresponding color filter CF of the color filter layer CFL and corresponding lens LS of the lens array LA. In an area adjacent to the non-display area NDA within the display area DA, the center of the color filter CF and the center of the lens LS may be offset in the plane direction relative to the center of the corresponding opening OP of the partition wall PW when viewed along the third direction DR3. For example, in the area adjacent to the non-display area NDA within the display area DA, each opening OP of the partition wall PW may partially overlap its corresponding color filter CF of the color filter layer CFL and corresponding lens LS of the lens array LA. Accordingly, light emitted from the emission structure EMS in the central portion of the display area DA may be efficiently directed in the normal direction to the display surface. Meanwhile, light emitted from the emission structure EMS near the perimeter of the display area DA may be efficiently directed at an angle inclined with respect to the normal direction of the display surface.

The overcoat layer OC may be disposed on the lens array LA. The overcoat layer OC may cover the optical function layer OFL, the encapsulation layer TFE, the emission structure EMS, and/or the pixel circuit layer PCL. The overcoat layer OC may include various materials suitable for protecting underlying layers from foreign substances such as dust, water, or the like. For example, the overcoat layer OCL may include at least one of an inorganic insulating layer and an organic insulating layer. For example, the overcoat layer OC may include an epoxy, but the embodiments are not limited thereto. The overcoat layer OC may have a lower refractive index than the lens array LA.

The cover window CW may be disposed on the overcoat layer OC. The cover window CW may be configured to protect underlying layers. The cover window CW may have a higher refractive index than the overcoat layer OC. The cover window CW may include glass, but embodiments are not limited thereto. For example, the cover window CW may include an encapsulation glass layer configured to protect components disposed thereunder. In other embodiments, the cover window CW may be omitted.

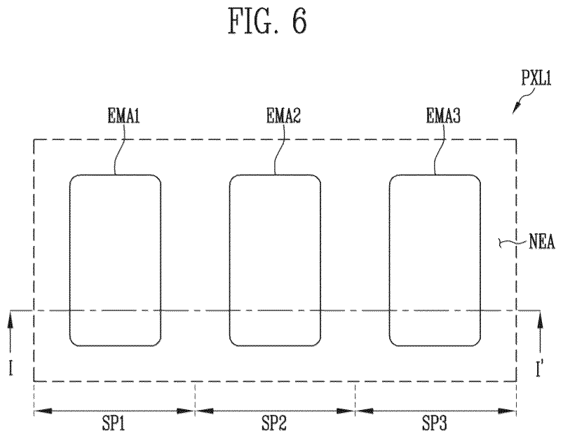

FIG. 6 is a plan view illustrating an embodiment of any one of the pixels of FIG. 5. In FIG. 6, for clarity and simplicity, only the first pixel PXL1 of the first and second pixels PXL1 and PXL2 of FIG. 5 is schematically depicted. The other pixels may be configured in the same manner as the first pixel PXL1.

Referring to FIGS. 5 and 6, the first pixel PXL1 may include first to third sub-pixels SP1 to SP3 arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a portion of the emission structure EMS (refer to FIG. 5) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3.

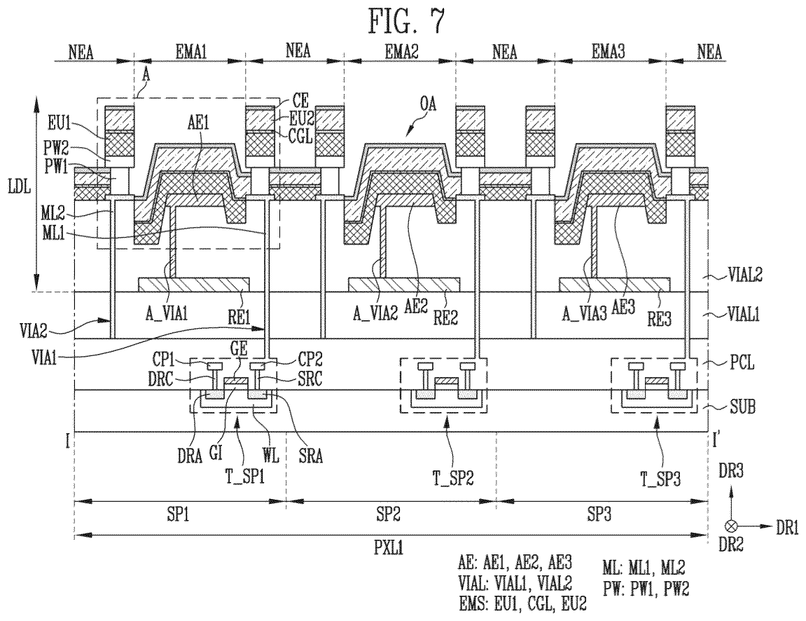

FIG. 7 is a sectional view taken along line I-I′ of FIG. 6 in accordance with an embodiment of the present disclosure. In FIG. 7, the optical functional layer OFL, the overcoat layer OC, and the cover window CW are omitted. FIG. 8 is a sectional view illustrating an emission structure EMS of FIG. 7.

Referring to FIG. 7, there are provided the substrate SUB and the pixel circuit layer PCL disposed on the substrate SUB.

The substrate SUB may include a silicon wafer substrate formed through a semiconductor process. For example, the substrate SUB may include silicon, germanium, and/or silicon-germanium.

The pixel circuit layer PCL may be disposed on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1. The transistor T_SP2 of the second sub-pixel SP2 may be any one of the transistors included in the sub-pixel circuit SPC of the second sub-pixel SP2. The transistor T_SP3 of the third sub-pixel SP3 may be any one of the transistors included in the sub-pixel circuit SPC of the third sub-pixel SP3. For example, each of the transistors T_SP1, T_SP2, and T_SP3 illustrated in FIG. 7 may correspond to the seventh transistor T7, which serves as the second initialization transistor illustrated in FIG. 3. In FIG. 7, only one transistor per sub-pixel is illustrated for clarity and simplicity, with the remaining circuit circuits omitted.

The transistor T_SP1 of the first sub-pixel SP1 may include a source area SRA, a drain area DRA, and a gate electrode GE.

The source area SRA and the drain area DRA may be disposed in the substrate SUB. Formed through an ion injection process, a well WL may be disposed in the substrate SUB. The source area SRA and the drain area DRA may be spaced apart from each other in the well WL. An area between the source area SRA and the drain area DRA in the well WL may be referred to as a channel area. The gate electrode GE may overlap the channel area between the source area SRA and the drain area DRA, and may be disposed in the pixel circuit layer PCL. The gate electrode GE may be spaced apart from the well WL or the channel area by an insulating material such as a gate insulating layer GI. The gate electrode GE may include a conductive material.

A plurality of layers included in the pixel circuit layer PCL may include insulating layers and conductive patterns disposed between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

As the gate electrode GE and the first and second conductive patterns CP1 and CP2 are connected to other circuit elements and/or lines, the transistor T_SP1 of the first sub-pixel SP1 may be implemented as one of the transistors of the first sub-pixel SP1.

Each of the transistor T_SP2 of the second sub-pixel SP2 and the transistor T_SP3 of the third sub-pixel SP3 may be configured in the same manner as the transistor T_SP1 of the first sub-pixel SP1.

Accordingly, the substrate SUB and the pixel circuit layer PCL may include the respective circuit elements of the first to third sub-pixels SP1 to SP3.

A via layer VIAL may be disposed on the pixel circuit layer PCL. The via layer VIAL may include a first via layer VIAL1 and a second via layer VIAL2. The first via layer VIAL1 may be disposed on the pixel circuit layer PCL to cover the pixel circuit layer PCL, and may feature an overall flat surface. The first via layer VIAL1 is configured to planarize stepped portions of the pixel circuit layer PCL. The first via layer VIAL1 may include at least one of silicon oxide (SiOₓ), silicon nitride (SiNₓ), and silicon carbon nitride (SiCN), but embodiments are not limited thereto.

The light-emitting-element layer LDL may be disposed on the first via layer VIAL1. The light-emitting-element layer LDL may include first to third reflective electrodes RE1 to RE3, the second via layer VIAL2, first to third anode electrodes AE1 to AE3, the partition wall PW, the emission structure EMS, and the cathode electrode CE. In an embodiment, the first to third reflective electrodes RE1 to RE3 may be omitted.

The first to third reflective electrodes RE1 to RE3 may be respectively disposed in the first to third sub-pixels SP1 to SP3 on the first via layer VIAL1. Each of the first to third reflective electrodes RE1 to RE3 may contact a circuit element disposed in the pixel circuit layer PCL through a corresponding via passing through the first via layer VIAL1.

The first to third reflective electrodes RE1 to RE3 may function as full mirrors, reflecting light emitted from the emission structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from among the aforementioned materials, but embodiments are not limited thereto. In an embodiment, the first to third reflective electrodes RE1 to RE3 may be formed of multiple layers including aluminum (Al) or silver (Ag), but the present disclosure is not limited thereto.

In embodiments, a connection electrode may be disposed under each of the first to third reflective electrodes RE1 to RE3. The connection electrode may enhance the electrical connection between the corresponding reflective electrode and the corresponding circuit element of the pixel circuit layer PCL. The connection electrode may have a multilayer structure. The multilayer structure may include titanium (Ti), titanium nitride (TiN), tantalum nitride (TaN), and the like, but embodiments are not limited thereto. In embodiments, a corresponding reflective electrode may be positioned between multiple layers of the connection electrode.

In an embodiment, a buffer pattern may be further disposed under at least one of the first to third reflective electrodes RE1 to RE3. The buffer pattern may include an inorganic material such as silicon carbon nitride, but embodiments are not limited thereto. With the buffer pattern in place, the height of the corresponding reflective electrode in the third direction DR3 may be adjusted.

The first to third reflective electrodes RE1 to RE3 may function as full mirrors, and the cathode electrode CE may function as a half mirror. For example, the combination of each of the first to third reflective electrodes RE1 to RE3 and the cathode electrode CE may form a resonant structure in the corresponding sub-pixel. Light emitted from the emission layer of the emission structure EMS may be amplified by reflecting back and forth between the corresponding reflective electrode and the cathode electrode CE. The amplified light can then be emitted through the cathode electrode CE. In this context, the distance between each reflective electrode and the cathode electrode CE can be interpreted as the resonant distance for the light emitted from the emission layer of the corresponding emission structure EMS.

To planarize the stepped portions between the first to third reflective electrodes RE1 to RE3, the second via layer VIAL2 may be disposed on the first via layer VIAL1 and the first to third reflective electrodes RE1 to RE3. The second via layer VIAL2 may cover overall surfaces of the first to third reflective electrodes RE1 to RE3 and the first via layer VIAL1.

The first to third anode electrodes AE1 to AE3 may be disposed on the second via layer VIAL2, overlapping the first to third reflective electrodes RE1 to RE3, respectively. When viewed in the third direction DR3, the first to third anode electrodes AE1 to AE3 may have shapes similar to the first to third emission areas EMA1 to EMA3 of FIG. 6. Each of the first to third anode electrodes AE1 to AE3 is connected to its corresponding one of the first to third reflective electrodes RE1 to RE3. The first anode electrode AE1 may be connected to the first reflective electrode RE1 through a first anode via hole A_VIA1 passing through the second via layer VIAL2. The second anode electrode AE2 may be connected to the second reflective electrode RE2 through a second anode via hole A_VIA2 passing through the second via layer VIAL2. The third anode electrode AE3 may be connected to the third reflective electrode RE3 through a third anode via hole A_VIA3 passing through the second via layer VIAL2.

In embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). However, the material of the first to third anode electrodes AE1 to AE3 is not limited to the aforementioned example. For example, the first to third anode electrodes AE1 to AE3 may include titanium nitride.

In an embodiment, each of the first to third anode electrodes AE1 to AE3 may be formed of a multilayer structure in which indium tin oxide (ITO), silver (Ag), indium tin oxide (ITO) are sequentially stacked. However, the present disclosure is not limited to the aforementioned example. In another embodiment, each of the first to third anode electrodes AE1 to AE3 may be formed of a single-layer structure including indium tin oxide (ITO).

A metal layer ML may be disposed on the via layer VIAL (or the second via layer VIAL2). The metal layer ML may include a first metal layer ML1 and a second metal layer ML2. The metal layer ML may contact the via layer VIAL (or the second via layer VIAL2). The first metal layer ML1 and the second metal layer ML2 may not physically contact each other. For example, in an embodiment, the first emission area EMA1 may separate the first metal layer ML1 and the second metal layer ML2, which are adjacent to the first emission area EMA1, from each other. The first metal layer ML1 may be electrically connected to the transistor T_SP1 through a first via hole VIA1 passing through the via layer VIAL (or the first via layer VIAL1 and the second via layer VIAL2). In other words, the first metal layer ML1 may be electrically connected to the transistor T_SP1 through the first via hole VIA1 that passes through the first via layer VIAL1 and the second via layer VIAL2. The first metal layer ML1 may be electrically connected to the seventh transistor T7 through the first via hole VIA1. The first via hole VIA1 may pass through at least a portion of the pixel circuit layer PCL. The second metal layer ML2 may be electrically connected to a line for supplying a second power voltage (e.g., cathode voltage) through a second via hole VIA2 passing through the via layer VIAL (or the first via layer VIAL1 and the second via layer VIAL2). In other words, the second via hole VIA2, may pass through both the first via layer VIAL1 and the second via layer VIAL2. The second via hole VIA2 may also pass through at least a portion of the pixel circuit layer PCL.

The metal layer ML (or each of the first metal layer ML1 and the second metal layer ML2) may include at least one of conductive materials. For example, the metal layer ML may include at least one of titanium (Ti), aluminum (Al), copper (Cu), and molybdenum titanium (MoTi). For example, the metal layer ML may be formed of a single layer including titanium (Ti), or multiple layers including at least one of titanium (Ti), aluminum (Al), copper (Cu), and molybdenum titanium (MoTi). For example, the metal layer ML may have any one of a multilayer structure including titanium (Ti) and aluminum (Al), a multilayer structure including titanium (Ti) and copper (Cu), and a multilayer structure including copper (Cu) and molybdenum titanium (MoTi).

The partition wall PW may be disposed on the via layer VIAL. At least a portion of the partition wall PW may be disposed on the metal layer ML. For example, a portion of the partition wall PW may be disposed on the first metal layer ML1, and a portion of the partition wall PW may be disposed on the second metal layer ML2. As an example, for the first and second metal layers ML1 and ML2 adjacent to the first emission area EMA1, the first emission area EMA1 may separate the portion of the partition wall PW disposed on the first metal layer ML1 from the portion of the partition wall PW disposed on the second metal layer ML2. A portion of the partition wall PW may contact the first metal layer ML1, and a portion of the partition wall PW may contact the second metal layer ML2.

In embodiments, the partition wall PW may include a plurality of inorganic including layers. For example, the partition wall PW may include a first partition wall layer PW1 and a second partition wall layer PW2 each of which is an inorganic insulating layer. For example, the first partition wall layer PW1 may include silicon nitride (SiNₓ), and the second partition wall layer PW2 may include silicon oxide (SiOₓ).

The first partition wall layer PW1 and the second partition wall layer PW2 may be stacked in a thickness direction of the pixel circuit layer PCL (e.g., the third direction DR3). For example, the first partition wall layer PW1 may be disposed on the via layer VIAL. At least a portion of the first partition wall layer PW1 may contact upper surfaces of the first metal layer ML1 and the second metal layer ML2. The second partition wall layer PW2 may be disposed on the first partition wall layer PW1. The second partition wall layer PW2 may contact an upper surface of the first partition wall layer PW1.

The first partition wall layer PW1 may have a width less than that of the second partition wall layer PW2. For example, the second partition wall layer PW2 may protrude further outward in the first direction DR1 or the second direction DR2 compared to the first partition wall layer PW1. In an embodiment, the partition wall PW may have a ‘T’-shaped structure. For example, the partition wall PW may form a tip structure (or an undercut structure) where the first partition wall layer PW1 is recessed further inward than the second partition wall layer PW2.

The partition wall PW may have a tip structure. When materials for forming the emission structure EMS are deposited, the emission structure EMS may be segmented into portions corresponding to the respective sub-pixels SPX1, SPX2, and SPX3, which are isolated from each other. For example, at least some layers of the emission structure EMS may be divided at the boundary areas between the sub-pixels SPX1, and SPX2, and SPX3. For example, at least some layers of the emission structure EMS may be separated at the boundary areas of the emission areas EMA1, EMA2, and EMA3 of the sub-pixels SPX1, and SPX2, and SPX3. This segmentation reduces the risk of leakage current flowing between adjacent sub-pixels SPX1, SPX2, and SPX3.

The emission structure EMS may be disposed on the anode electrodes AE filling the openings OP in the partition wall PW. Additionally, at least a portion of the emission structure EMS may be disposed on the partition wall PW. As described above, the emission structure EMS may be divide by the partition wall PW between adjacent sub-pixels SPX1, SPX2, and SPX3 during deposition. This separation reduces the risk of current leakage from each of the first to third sub-pixels SP1 to SP3 to adjacent sub-pixels through the layers of the emission structure EMS during the operation of the display panel DP. As a result, the first to third light emitting elements LD1 to LD3 may operate with relatively high reliability.

Referring to FIG. 8, the emission structure EMS may have a tandem structure in which first and second emission components EU1 and EU2 are stacked. The emission structure may have a substantially identical configuration in each of the first to third light emitting elements LD1 to LD3 of FIG. 7.

Each of the first and second emission components EU1 and EU2 may include at least one emission layer configured to generate light in response to current applied thereto. The first emission component EU1 may include a first emission layer EML1, a first electron transport component ETU1, and a first hole transport component HTU1. The first emission layer EML1 may be disposed between the first electron transport component ETU1 and the first hole transport component HTU1. The second emission component EU2 may include a second emission layer EML2, a second electron transport component ETU2, and a second hole transport component HTU2. The second emission layer EML2 may be disposed between the second electron transport component ETU2 and the second hole transport component HTU2.

Each of the first and second hole transport components HTU1 and HTU2 may include at least one of a hole injection layer and a hole transport layer, and may further include a hole buffer layer, an electron blocking layer, and the like. The first and second hole transport components HTU1 and HTU2 may have the same configuration or have different configurations.

Each of the first and second electron transport components ETU1 and ETU2 may include at least one of an electron injection layer and an electron transport layer, and may further include an electron buffer layer, a hole blocking layer, and the like. The first and second electron transport components ETU1 and ETU2 may have the same configuration or have different configurations.

A connection layer, which may be implemented as a charge generation layer CGL, may be disposed between the first emission component EU1 and the second emission component EU2 to connect the first and second emission components EU1 and EU2 to each other. In particular, the charge generation layer CGL may electrically connect the first emission component EU1 and the second emission component EU2 to each other. In embodiments, the charge generation layer CGL may have a stacked structure including a p-dopant layer and an n-dopant layer. For example, the p-dopant layer may include a p-type dopant such as 1,4,5,8,9,11-hexaazatriphenylene hexacarbonitrile (HAT-CN), tetracyanoquinodimethane (TCNQ), or 2-(7-Dicyanomethylene-1,3,4,5,6,8,9,10-octafluoro-7H-pyren-2-ylidene)-malononitrile (NDP-9), and the n-dopant layer may include alkali metal, alkaline earth metal, lanthanide metal, or a combination thereof. However, embodiments are not limited to the aforementioned example.

In embodiments, the first emission layer EML1 and the second emission layer EML2 may emit light in different colors. The light emitted from the first emission layer EML1 and the second emission layer EML2 may combine to produce white light. For instance, the first emission layer EML1 may generate blue light, and the second emission layer EML2 may generate yellow light. In embodiments, the second emission layer EML2 may have a stacked structure including a first sub-emission layer configured to generate red light, and a second sub-emission layer configured to generate green light. The red and green light may mix to produce yellow light. In such cases, an intermediate layer configured to transport holes and/or block the transport of electrons may be included between the first and second sub-emission layers to enhance performance.

In other embodiments, the first emission layer EML1 and the second emission layer EML2 may generate light of the same color.

The cathode electrode CE may be disposed on the emission structure EMS. The cathode electrode CE may act as a half mirror, allowing it to partially transmit and partially reflect the light emitted from the emission structure EMS.

The first anode electrode AE1, the portion of the emission structure EMS that overlaps the first anode electrode AE1, and the portion of the cathode electrode CE that overlaps the first anode electrode AE1 may form a first light emitting element. The second anode electrode AE2, the portion of the emission structure EMS that overlaps the second anode electrode AE2, and the portion of the cathode electrode CE that overlaps the second anode electrode AE2 may form a second light emitting element. The third anode electrode AE3, the portion of the emission structure EMS that overlaps the third anode electrode AE3, and the portion of the cathode electrode CE that overlaps the third anode electrode AE3 may form a third light emitting element.

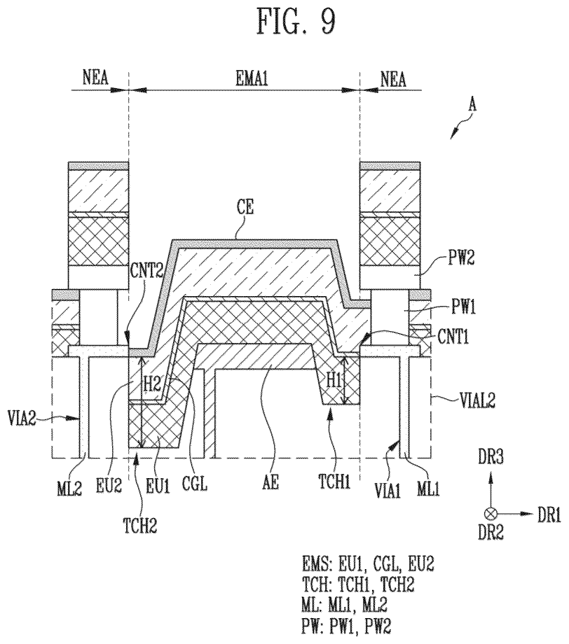

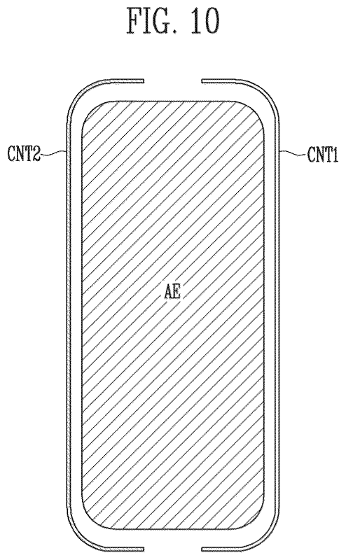

FIG. 9 is a sectional view illustrating an enlargement of area A of FIG. 7. FIG. 10 is a plan view for explaining a contact area in accordance with an embodiment of the present disclosure. To illustrate the arrangement relationship between contact areas (CNT1 and CNT2) and the anode electrode AE, FIG. 10 provides a schematic plan view of the anode electrode AE.

Referring to FIGS. 7 and 9, the via layer VIAL (or the second via layer VIAL2) may include a trench TCH. The trench TCH may enclose an area where the anode electrode AE is disposed. The trench TCH may include a first trench TCH1 and a second trench TCH2. The first trench TCH1 and the second trench TCH2 may each refer to a groove formed in the via layer VIAL (or the second via layer VIAL2). The first trench TCH1 and the second trench TCH2 may each form a stepped portion on a surface (e.g., an upper surface) of the via layer VIAL (or the second via layer VIAL2).

The first trench TCH1 may be adjacent to the first metal layer ML1. For example, the first trench TCH1 may be disposed closer to the first metal layer ML1 than the second metal layer ML2. The second trench TCH2 may be adjacent to the second metal layer ML2. For example, the second trench TCH2 may be disposed closer to the second metal layer ML2 than the first metal layer ML1.

In an embodiment, the first trench TCH1 and the second trench TCH2 may have different heights. For example, the first trench TCH1 may have a first trench height H1. The second trench TCH2 may have a second trench height H2. The second trench height H2 may be greater than the first trench height H1. A trench height may be defined as a linear distance from the bottom of the trench to the upper surface of the second via layer VIAL2.

The anode electrode AE may not be positioned within either the first trench TCH1 or the second trench TCH2. For example, the anode electrode AE may not overlap with either the first trench TCH1 or the second trench TCH2.

The anode electrode AE may feature a forward-tapered side surface. “Forward-tapered” indicates that the width (e.g., the width defined in the first direction DR1 or the second direction DR2) decreases as the anode electrode AE extends in the third direction DR3. This forward-tapered design helps prevent the charge generation layer CGL from being short-circuited at the edges of the anode electrode AE.

The first emission component EU1 may be disposed on the anode electrode AE, and at least a portion of the first emission component EU1 may be disposed in the first trench TCH1 and the second trench TCH2. In other words, the first emission component EU1 may be in direct contact with the anode electrode AE, the bottom of the first trench TCH1 and the bottom of the second trench TCH2. At least a portion of each of the first trench TCH1 and the second trench TCh2 may be filled with the first emission component EU1. Since the second via layer VIAL2 includes the first trench TCH1 and the second trench TCH2, a surface (e.g., an upper surface) of the first emission component EU1 may exhibit a stepped profile. For example, the upper surface of the first emission component EU1 in an area overlapping the first trench TCH1 may be higher than the upper surface of the first emission component EU1 in an area overlapping the second trench TCH2 with respect to the third direction DR3.

The charge generation layer CGL may be disposed on the first emission component EU1, and at least a portion of the charge generation layer CGL may be disposed in the first trench TCH1 and the second trench TCH2. The charge generation layer CGL may be in direct contact with the first emission component EU1 Since the second via layer VIAL2 includes the first trench TCH1 and the second trench TCH2, a surface (e.g., an upper surface) of the charge generation layer CGL may exhibit a stepped profile. For example, the upper surface of the charge generation layer CGL in the area overlapping the first trench TCH1 may be higher than the upper surface of the charge generation layer CGL in the area overlapping the second trench TCH2 with respect to the third direction DR3.

The charge generation layer CGL may be in physical contact with the first metal layer ML1 in the area overlapping (or adjacent to) the first trench TCH1. For example, referring to FIGS. 9 and 10, the charge generation layer CGL may be in physical contact with the first metal layer ML1 in the first contact area CNT1. The first contact area CNT1 may be spaced apart from the anode electrode AE and positioned around the anode electrode AE. The first contact area CNT1 may be located near (or on) an upper surface of the second via layer VIAL2 where the first metal layer ML1 and the charge generation layer CGL meet. For example, the first contact area CNT1 may not overlap the anode electrode AE in a plan view. For example, in a plan view, the first contact area CNT1 may be spaced apart from the anode electrode AE and partially surround the periphery of the anode electrode AE. In an embodiment, the first contact area CNT1 may enclose only a portion of the anode electrode AE rather than fully encircling its periphery.

The charge generation layer CGL may be in contact with the first metal layer ML1, thereby establishing an electrical connection between the charge generation layer CGL and the first metal layer ML1. The first metal layer ML1 may also be electrically connected to the seventh transistor T7, and, as a result, may receive the second initialization voltage.

The charge generation layer CGL may transmit the supplied second initialization voltage to the second emission component EU2. If the second emission component EU2 is not fully initialized, a black floating phenomenon may occur, where a fully black color is not displayed on the display panel DP, and a faint color appears instead when power is not supplied to the sub-pixels SP1, SP2, and SP3 (e.g., when a black color is intended to be displayed). In contrast, the present disclosure provides a configuration where the second emission component EU2 can be initialized by separately supplying the second initialization voltage to the charge generation layer CGL, thereby preventing the black floating phenomenon.

The charge generation layer CGL may not be in physical contact with the second metal layer ML2. For example, in the area overlapping the second trench TCH2, the charge generation layer CGL may not be in physical contact with the second metal layer ML2.

The charge generation layer CGL may be segmented by the partition wall PW between the first to third sub-pixels SP1, SP2, and SP3. For example, the charge generation layer CGL may be severed at the boundaries of the partition wall PW, ensuring that it is not electrically connected between the first to third sub-pixels SP1, SP2, and SP3. As a result, current cannot flow through the charge generation layer CGL between the first to third sub-pixels SP1, SP2, and SP3, effectively preventing leakage current from occurring between the first to third sub-pixels SP1, SP2, and SP3.

The display device 100 in accordance with the present disclosure may include a structure (e.g., the trench TCH, the partition wall PW, and the metal layer ML) to prevent leakage current between the first to third sub-pixels SP1, SP2, and SP3, thereby enhancing its reliability. Furthermore, in an embodiment, when the display device 100 is implemented as an HIAA display device, the structure can also prevent moisture penetration in an area where a hole is formed in the display area DA.

The second emission component EU2 may be disposed on the charge generation layer CGL, and at least a portion of the second emission component EU2 may be disposed in the second trench TCH2. Since the second via layer VIAL2 includes the first trench TCH1 and the second trench TCH2, a surface (e.g., an upper surface) of the second emission component EU2 may exhibit a stepped profile.

In an embodiment, the second emission component EU2 may be in contact with a side surface of the partition wall PW in the area overlapping (or adjacent to) the first trench TCH1. The second emission component EU2 may not be in contact with the side surface of the partition wall PW in the area overlapping (or adjacent to) the second trench TCH2.

The cathode electrode CE may be disposed on the second emission component EU2. Since the second via layer VIAL2 includes the first trench TCH1 and the second trench TCH2, a surface (e.g., an upper surface) of the cathode electrode CE may have a stepped portion.

The cathode electrode CE may be in physical contact with the second metal layer ML2 in the area overlapping (or adjacent to) the second trench TCH2. For example, referring to FIGS. 9 and 10, the cathode electrode CE may be in physical contact with the second metal layer ML2 in the second contact area CNT2. The second contact area CNT2 may be spaced apart from the anode electrode AE and positioned around the anode electrode AE. For example, the second contact area CNT2 may not overlap the anode electrode AE in a plan view. For example, in a plan view, the second contact area CNT2 may be spaced apart from the anode electrode AE and enclose at least a portion of the periphery of the anode electrode AE. In an embodiment, the second contact area CNT2 may enclose only a portion of the anode electrode AE rather than completely enclosing the periphery of the anode electrode AE. The second contact area CNT2 may be physically separated from the first contact area CNT1.

The cathode electrode CE may be in contact with the second metal layer ML2, establishing an electrical connection between the cathode electrode CE and the second metal layer ML2. The second metal layer ML2 may, in turn, be electrically connected to the line supplying the second power voltage and, as a result, may receive the second power voltage (e.g., cathode voltage).

The cathode electrode CE may not be in physical contact with the first metal layer ML1. For example, in the area overlapping (or adjacent to) the first trench TCH1, the cathode electrode CE may not be in physical contact with the first metal layer ML1. Rather, the cathode electrode CE may be in contact with the partition wall PW.

The cathode electrode CE and the charge generation layer CGL may share the same configuration in the first to third sub-pixels SP1, SP2, and SP3, enabling each of the first to third sub-pixels SP1, SP2, and SP3 to be individually controlled by the second power voltage and the second initialization voltage supplied to them.

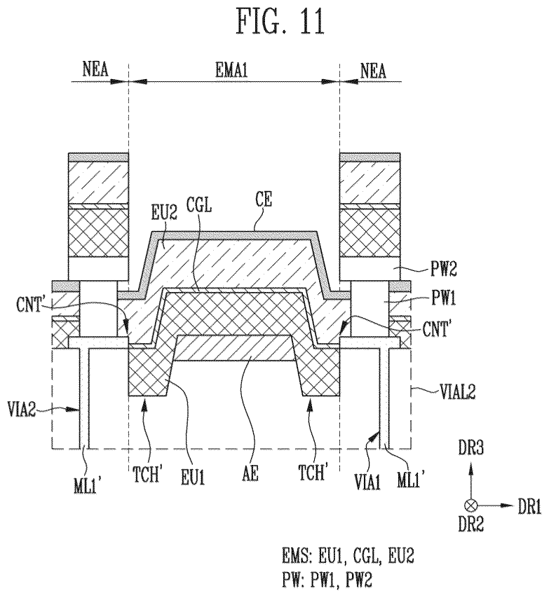

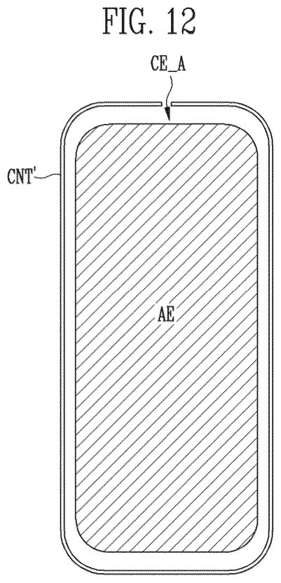

FIG. 11 is a sectional view of a display panel in accordance with another embodiment of the present disclosure. FIG. 12 is a plan view for explaining a contact area CNT′ in accordance with another embodiment. To illustrate the arrangement relationship between the contact area CNT′ and the anode electrode AE, FIG. 12 presents a schematic plan view of the anode electrode AE.

The embodiment illustrated in FIG. 11 differs from the embodiment illustrated in FIG. 9 in that trenches do not have different heights. Hereinafter, descriptions of elements or features already discussed above will be omitted.

Referring to FIG. 11, a trench TCH′ may be formed to have the same (or uniform) height.

A first metal layer ML1′ may be connected to the first via hole VIA1 and the second via hole VIA2. The first metal layer ML1′ may be electrically connected to the transistor T_SP1 through the first via hole VIA1 and the second via hole VIA2 that pass through the via layer VIAL (or the first via layer VIAL1 and the second via layer VIAL2). The first metal layer ML1′ may be electrically connected to the seventh transistor T7 through the first via hole VIA1 and the second via hole VIA2.

The charge generation layer CGL may be in physical contact with the first metal layer ML1′ in an area overlapping the trench TCH′. For example, referring to FIGS. 11 and 12, the charge generation layer CGL may be in physical contact with the first metal layer ML1′ in the contact area CNT′. The contact area CNT′ may be spaced apart from the anode electrode AE and positioned around the anode electrode AE. For example, the contact area CNT′ may not overlap the anode electrode AE in a plan view. For example, in a plan view, the contact area CNT′ may be spaced apart from the anode electrode AE and enclose at least a portion of a periphery of the anode electrode AE. In an embodiment, the contact area CNT′ may enclose only a portion of the anode electrode AE rather than completely enclosing the periphery of the anode electrode AE.

The cathode electrode CE may span the first to third sub-pixels SP1, SP2, and SP3 (e.g., the cathode electrode CE may extend across the first to third sub-pixels SP1 to SP3), and supply a cathode voltage to the first to third sub-pixels SP1, SP2, and SP3 over the emission structure EMS through a cathode voltage application area CE_A. For example, the cathode electrode CE may receive the cathode voltage at a position higher than the plane on which the first metal layer ML1′ is disposed.

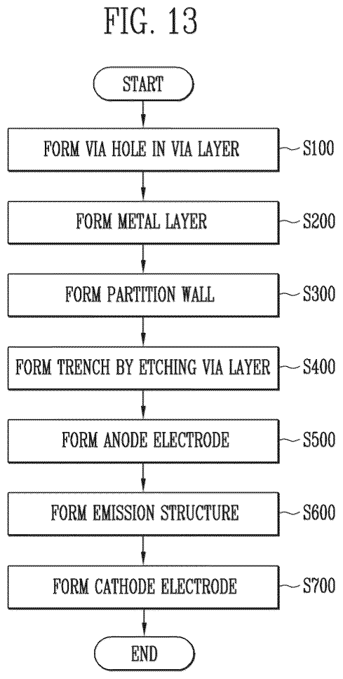

Hereinafter, a method of manufacturing the display device 100 in accordance with an embodiment of the present disclosure will be described with reference to FIGS. 13 to 18. Descriptions of elements of details that overlap with the previously described content will be omitted.

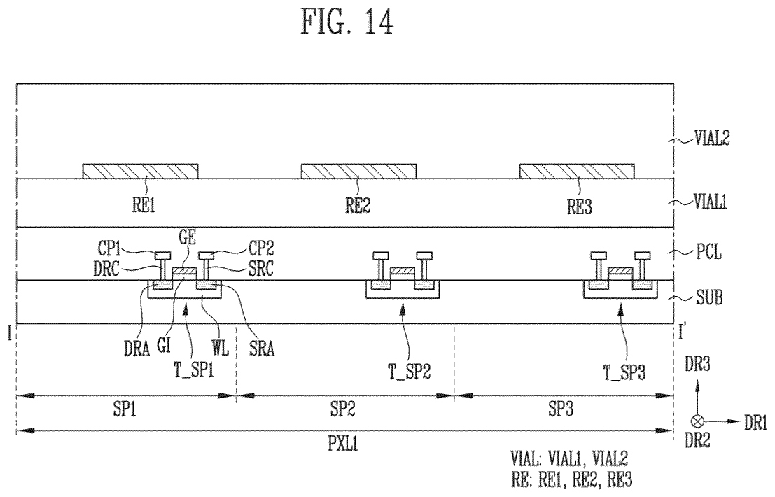

FIG. 13 is a flowchart illustrating a method of manufacturing the display device 100. FIGS. 14 to 18 are schematic sectional views illustrating a method of manufacturing the display device 100 in accordance with an embodiment of the present disclosure.

Referring to FIG. 13, the method of manufacturing the display device 100 may include step S100 of forming a via hole in a via layer, step S200 of forming a metal layer, step S300 of forming a partition wall, step S400 of forming a trench by etching the via layer, step S500 of forming an anode electrode, step S600 of forming an emission structure, and step S700 of forming a cathode electrode.

Referring to FIG. 14, before step S100 of forming the via hole in the via layer, the pixel circuit layer PCL including conductive layers constituting the sub-pixel circuit SPC for driving the light emitting elements LD and insulating layers disposed between the conductive layers may be formed on the substrates SUB.

After the step of forming the pixel circuit layer PCL, the step of forming the via layer VIAL may be performed. The step of forming the via layer VIAL may include the step of forming the first via layer VIAL1 and the step of forming the second via layer VIAL2. The first via layer VIAL1 may be formed on the pixel circuit layer PCL. The second via layer VIAL2 may be formed on the first via layer VIAL1.

In an embodiment, the step of forming the reflective electrode RE may be performed between the step of forming the first via layer VIAL1 and the step of forming the second via layer VIAL2. The step of forming the reflective electrode RE may include the step of forming the first to third reflective electrodes RE1 to RE3. The first reflective electrode RE1 may be formed in an area where the first sub-pixel SP1 is defined. The second reflective electrode RE2 may be formed in an area where the second sub-pixel SP2 is defined. The third reflective electrode RE3 may be formed in an area where the third sub-pixel SP3 is defined.

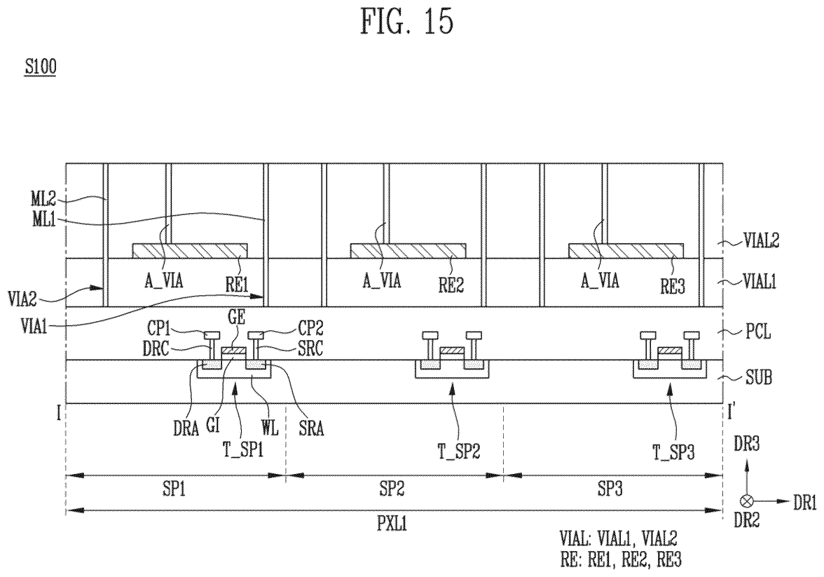

Referring to FIG. 15, step S100 of forming the via hole in the via layer may include the step of forming the anode via hole A_VIA, the first via hole VIAL, and the second via hole VIA2 in the via layer VIAL. The anode via hole A_VIA, the first via hole VIAL, and the second via hole VIA2 may be formed through a photo lithography process. The anode via hole A_VIA, the first via hole VIA1, and the second via hole VIA2 may be formed substantially in the same configuration across the regions defined by the first to third sub-pixels SP1 to SP3.

The anode via hole A_VIA may be formed to pass through the second via layer VIAL2 and overlap the reflective electrode RE. The reflective electrode RE may contact the anode via hole A_VIA.

The first via hole VIA1 and the second via hole VIA2 may each be formed to pass through the second via layer VIAL2 and the first via layer VIAL1. Additionally, each of the first via hole VIA1 and the second via hole VIA2 may be formed to pass through at least a portion of the pixel circuit layer PCL. The first via hole VIA1 and the second via hole VIA2 may be formed in an area that does not overlap the anode electrode AE.

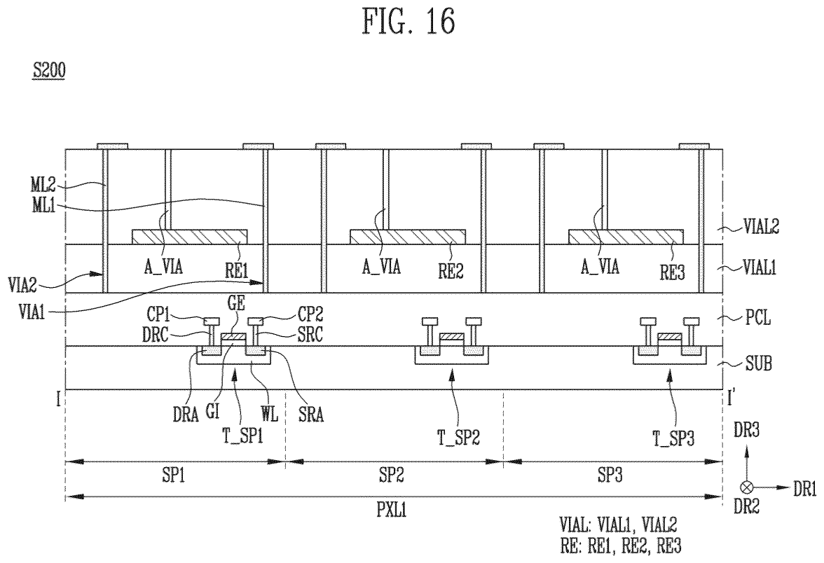

Referring to FIG. 16, step S200 of forming the metal layer may include the step of forming the first metal layer ML1 and the second metal layer ML2. The step of forming the first metal layer ML1 and the second metal layer ML2 may include the step of forming a base metal layer by depositing a material for forming the first metal layer ML1 and the second metal layer ML2, and the step of etching the base metal layer. The base metal layer may be etched, thereby forming the first metal layer ML1 and the second metal layer ML2.

In an embodiment, one or more of a chemical vapor deposition (CVD) process and an atomic layer deposition (ALD) process may be used to deposit layers in the configuration of the display device 100. In an embodiment, one or more of wet etching and dry etching may be used as the etching process. However, the present disclosure is not limited to a specific example.

The first metal layer ML1 and the second metal layer ML2 may be formed through the same process. For example, the first metal layer ML1 and the second metal layer ML2 may be formed through the same etching process. The first metal layer ML1 and the second metal layer ML2 may be disposed on the same plane. For example, the first metal layer ML1 and the second metal layer ML2 may be disposed on the second via layer VIAL2 and be in contact with the second via layer VIAL2.

At step S200 of forming the metal layer, the first metal layer ML1 may be formed. The first via hole VIA1 may be filled with the first metal layer ML1. The first metal layer ML1 may contact the first via hole VIA1. At step S200 of forming the metal layer, the second metal layer ML2 may be formed. The second via hole VIA2 may be filled with the second metal layer ML2. The second metal layer ML2 may contact the second via hole VIA2. At step S200 of forming the metal layer, the first metal layer ML1 may be electrically connected to the seventh transistor T7, and the second metal layer ML2 may be electrically connected to the line for supplying a second power voltage (e.g., cathode voltage).

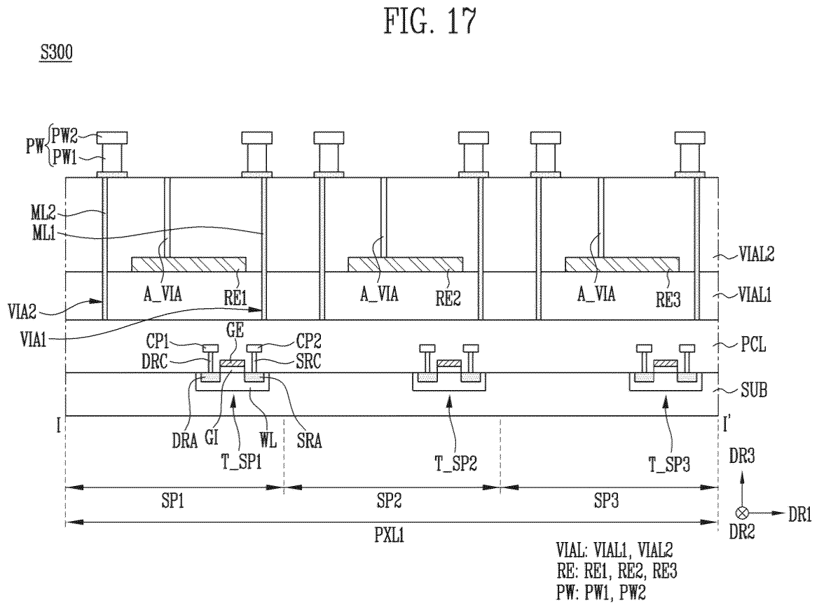

Referring to FIG. 17, at the step of forming the partition wall PW, the partition wall PW with a multilayered stack structure may be formed. For example, the step of forming the partition wall PW may include the step of forming the first partition wall layer PW1 and the step of forming the second partition wall layer PW2. At least a portion of the partition wall PW may be formed on the first metal layer ML1. At least a portion of the partition wall PW may be formed on the second metal layer ML2.

The step of forming the partition wall PW may include the step of forming a first base partition wall layer by depositing a material for forming the first partition wall layer PW1, the step of forming a second base partition wall layer by depositing a material for forming the second partition wall layer PW2, and the step of etching the first base partition wall layer and the second base partition wall layer. The first base partition wall layer and the second base partition wall layer may be etched, thereby respectively forming the first partition wall layer PW1 and the second partition wall layer PW2. The first base partition wall may be etched deeper than the second base partition wall layer, so that the second partition wall layer PW2 may protrude further toward a peripheral area (or outward) than the first partition wall layer PW1. In other words, the second partition wall layer PW2 may be wider than the first partition wall layer PW1 in the first direction DR1.

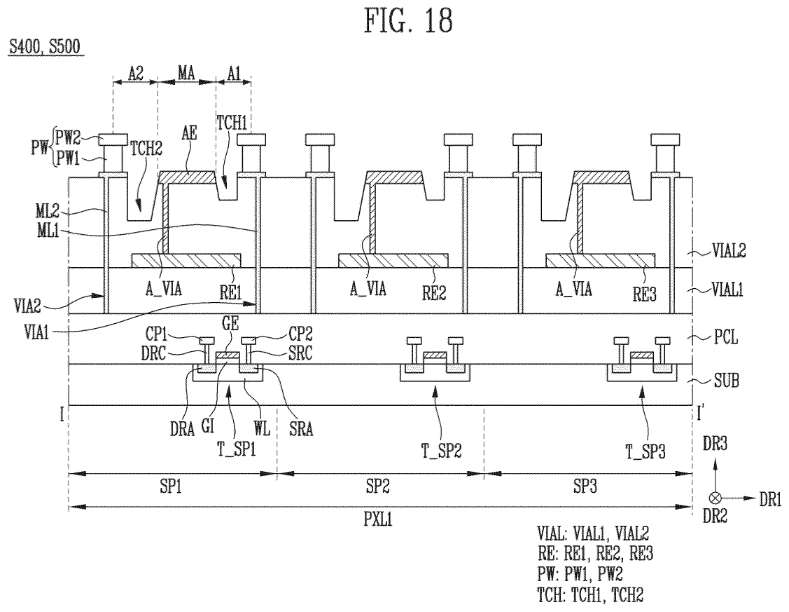

Referring to FIG. 18, step S400 of forming the trench by etching the via layer may include the step of forming the trench TCH by etching the via layer VIAL (e.g., the second via layer VIAL2). The step of forming the trench TCH may include the step of forming the first trench TCH1 and the step of forming the second trench TCH2.

Each of the areas where the first to third sub-pixels SP1, SP2, and SP3 are defined may include a first trench area A1, a second trench area A2, and an intermediate area MA. The first trench area A1 may correspond to an area where the first trench TCH1 is to be formed by etching the second via layer VIAL2. The first trench area A1 may be adjacent to the first metal layer ML1. The second trench area A2 may correspond to an area where the second trench TCH2 is to be formed by etching the second via layer VIAL2. The second trench area A2 may be adjacent to the second metal layer ML2. The intermediate area MA may be an area enclosed by the trench TCH, and may correspond to an area where the anode electrode AE is to be disposed.

The step of forming the first trench TCH1 may include the step of disposing a photoresist to overlap the second trench area A2 and the intermediate area MA, followed by the step of etching the second via layer VIAL2 overlapping the first trench area A1. During the step of forming the first trench TCH1, the photoresist may be excluded from the area overlapping the first trench area A1, allowing the first trench TCH1 to be formed by etching the second via layer VIAL2 in the region overlapping the first trench area A1.

The step of forming the second trench TCH2 may include the step of disposing a photoresist to overlap the first trench area A1 and the intermediate area MA, followed by the step of etching the second via layer VIAL2 overlapping the second trench area A2. During the step of forming the second trench TCH2, the photoresist may be excluded from the area overlapping the second trench area A2, allowing the second trench TCH2 to be formed by etching the second via layer VIAL2 in the region overlapping the second trench area A2.

Alternatively, in an embodiment, the step of forming the first trench TCH1 and the second trench TCH2 may include the step of disposing the photoresist to overlap the first trench area A1, the second trench area A2, and the intermediate area MA, followed by the step of etching the second via layer VIAL2 overlapping the first trench area A1, the second trench area A2, and the intermediate area MA. In this case, the photoresist may have different thicknesses in respective areas overlapping the first trench area A1, the second trench area A2, and the intermediate area MA. For example, the photoresist may have its greatest thickness in the area overlapping the intermediate area MA, and its smallest thickness in the area overlapping the second trench area A2. For example, the photoresist disposed in the first trench area A1 and the second trench area A2 may be halftone photoresist.

During the step of forming the trench TCH, the second trench TCH2 may be etched deeper than the first trench TCH1, and a height of the second trench TCH2 may be greater than that of the first trench TCH1. Accordingly, a surface of the second via layer VIAL2 may have a stepped portion.

After step S400 of forming the trench by etching the via layer, step S500 of forming the anode electrode may be performed. At step S500 of forming the anode electrode, the anode electrode AE may be formed on the second via layer VIAL2. The anode electrode AE may be formed in the area overlapping the intermediate area MA. The anode electrode AE may be formed to have a forward-tapered side surface.

Referring to FIGS. 9 and 13, step S600 of forming the emission structure may include the step of forming the first emission component EU1, the step of forming the charge generation layer CGL on the first emission component EU1, and the step of forming the second emission component EU2 on the charge generation layer CGL. The first emission component EU1, the charge generation layer CGL, and the second emission component EU2 may be deposited through a deposition process.

During the step of forming the charge generation layer CGL, the charge generation layer CGL may be formed. The charge generation layer CGL may be in physical contact with the first metal layer ML1 in the area overlapping the first trench TCH1. The charge generation layer CGL may not be in physical contact with the second metal layer ML2 in the area overlapping the second trench TCH2.

After step S600 of forming the emission structure, step S700 of forming the cathode electrode may be performed. At step S700 of forming the cathode electrode, the cathode electrode CE may be formed. The cathode electrode CE may be in physical contact with the second metal layer ML2 in the area overlapping the second trench TCH2. The cathode electrode CE may not be in physical contact with the first metal layer ML1 in the area overlapping the first trench TCH1.

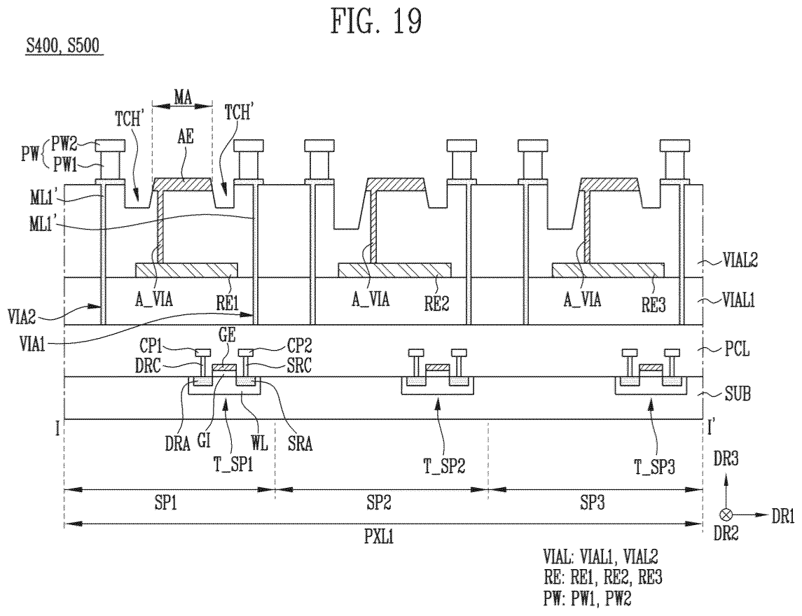

Hereinafter, a method of manufacturing the display device 100 in accordance with an embodiment of the present disclosure will be described with reference to FIGS. 11, 13, and 19. FIG. 19 is a schematic sectional view illustrating a method of manufacturing the display device 100 in accordance with an embodiment of the present disclosure.

Referring to FIGS. 11, 13, and 19, step S200 of forming the metal layer may include the step of forming a first metal layer ML1′. The step of forming the first metal layer ML1′ may include the step of forming a base metal layer by depositing a material for forming the first metal layer ML1′, and the step of etching the base metal layer. The base metal layer may be etched, thereby forming the first metal layer ML1′.

At step S200 of forming the metal layer, the first metal layer ML1′ may be formed. The first via hole VIA1 and the second via hole VIA2 may be filled with the first metal layer ML1′. The first metal layer ML1′ may contact the first via hole VIA1 and the second via hole VIA2.

Step S400 of forming the trench by etching the via layer may include the step of forming a trench TCH′ having a uniform height. The trench TCH′ may be formed along a periphery of the intermediate area MA, and may have a uniform height. For example, in an area where the trench TCH′ is formed, the second via layer VIAL2 may be etched to a uniform thickness.

During the step of forming the charge generation layer CGL, the charge generation layer CGL may be formed. The charge generation layer CGL may be in physical contact with the first metal layer ML1′ in the area overlapping the trench TCH′.

The charge generation layer CGL may be severed on a boundary surface of the partition wall PW. As a result, current may not flow between the first to third sub-pixels SP1, SP2, and SP3 through the charge generation layer CGL.

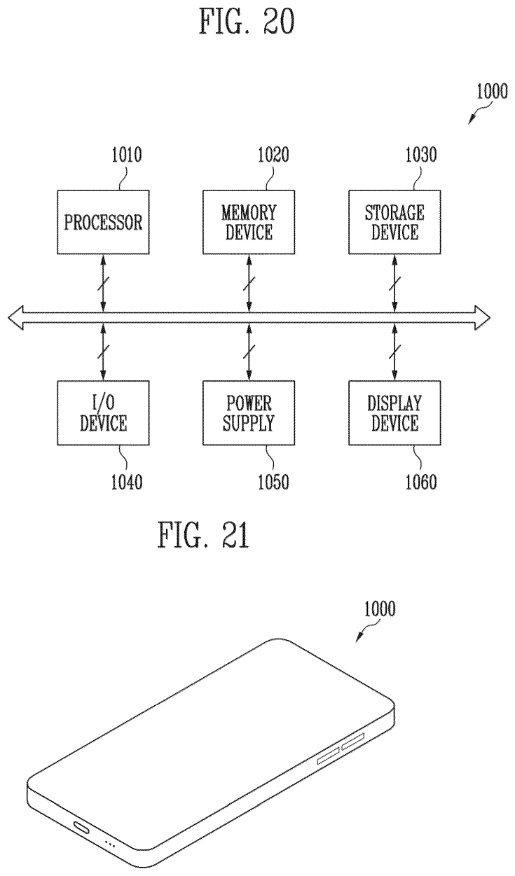

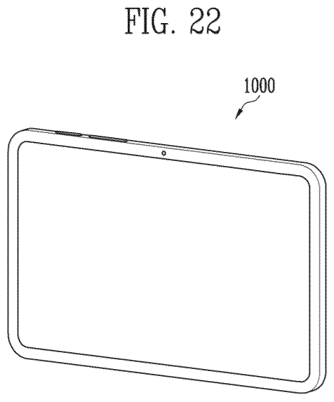

FIG. 20 is a schematic block diagram illustrating an electronic device 1000 including a display device in accordance with an embodiment of the present disclosure. FIG. 21 is a schematic diagram illustrating an example where the electronic device 1000 of FIG. 20 is a smartphone. FIG. 22 is a schematic diagram illustrating an example where the electronic device 1000 of FIG. 20 is a tablet computer.

Referring to FIGS. 20 to 22, the electronic device 1000 may include a processor 1010, a memory device 1020, a storage device 1030, an input/output (I/O) device 1040, a power supply 1050, and a display device 1060. The display device 1060 may be the display device 100 of FIG. 1. The electronic device 1000 may further include various ports for communication with a video card, a sound card, a memory card, a USB device, or other systems. In an embodiment, as illustrated in FIG. 21, the electronic device 1000 may be a smartphone. In an embodiment, as illustrated in FIG. 22, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Embodiments of the present disclosure may provide a display device, an electronic device and a method of manufacturing the display device, capable of reducing leakage current between adjacent sub-pixels.

While various example embodiments have been described above, those skilled in the art will appreciate that various modifications, additions and substitutions are possible, without departing from the scope and spirit of the present disclosure.

Therefore, the embodiments disclosed in this specification are provided for illustrative purposes and should not be considered as limiting the technical spirit of the present disclosure.

What is claimed is:

1. A display device, comprising:
a pixel circuit layer;
a via layer disposed on the pixel circuit layer, wherein the via layer includes a trench;
a first via hole and a second via hole passing through the via layer;
a first metal layer electrically connected to the pixel circuit layer through the first via hole;
an anode electrode disposed on the via layer;
a first emission component disposed on the anode electrode;
a charge generation layer disposed on the first emission component; and
a second emission component disposed on the charge generation layer,
wherein the pixel circuit layer comprises:
a transistor electrically connected to an initialization voltage node, wherein the initialization voltage node is configured to transmit an initialization voltage, and
wherein the transistor is electrically connected to the charge generation layer through the first metal layer.

2. The display device according to claim 1, further comprising a partition wall disposed on the first metal layer,
wherein the partition wall comprises:
a first partition wall layer; and
a second partition wall layer disposed on the first partition wall layer,
wherein the second partition wall layer is wider in a direction parallel to a surface of a substrate than the first partition wall layer.

3. The display device according to claim 2,
wherein the trench includes a first trench and a second trench, and
wherein a height of the first trench is less than a height of the second trench.

4. The display device according to claim 3, further comprising:
a second metal layer electrically connected to the pixel circuit layer through the second via hole; and
a cathode electrode disposed on the second emission component,
wherein the second metal layer is in contact with the cathode electrode in an area adjacent to or overlapping the second trench.

5. The display device according to claim 4,
wherein the first metal layer and the second metal layer are disposed on an identical plane,
wherein the first partition wall layer is in contact with the first metal layer, and
wherein an upper surface of each of the first emission component, the charge generation layer, and the second emission component has a stepped portion.

6. The display device according to claim 4, wherein the first metal layer is in contact with the charge generation layer in an area adjacent to or overlapping the first trench.

7. The display device according to claim 4, wherein the charge generation layer is not in contact with the second metal layer.

8. The display device according to claim 1,
wherein the first metal layer is in contact with the charge generation layer in a first contact area, and
wherein, in a plan view, the first contact area is spaced apart from the anode electrode, and encloses at least a portion of a periphery of the anode electrode.

9. The display device according to claim 8, further comprising:
a second metal layer electrically connected to the pixel circuit layer through the second via hole; and
a cathode electrode disposed on the second emission component,
wherein the cathode electrode is in contact with the second metal layer in a second contact area, and
wherein, in a plan view, the second contact area encloses at least a portion of the periphery of the anode electrode.

10. The display device according to claim 1, wherein the first metal layer is a single layer including titanium (Ti), or multiple layers including at least one of titanium (Ti), aluminum (Al), copper (Cu), and molybdenum titanium (MoTi).

11. The display device according to claim 1, wherein a side surface of the anode electrode is forward-tapered.

12. The display device according to claim 1, further comprising a display area where pixels are disposed, first sub-pixel and a second sub-pixel, wherein
the display device is a hole in active area (HIAA) display device, and a hole is formed in the display area, and
wherein the charge generation layer is not electrically connected between the first sub-pixel and the second sub-pixel.

13. The display device according to claim 1,
wherein the first metal layer is electrically connected to the pixel circuit layer through the second via hole,
wherein the first metal layer is in contact with the charge generation layer in a contact area, and
wherein, in a plan view, the contact area encloses a first portion of a periphery of the anode electrode, and does not enclose a second portion of the periphery of the anode electrode.

14. A method of manufacturing a display device, comprising:
forming a pixel circuit layer including a transistor;
forming a via layer on the pixel circuit layer;
forming a first via hole and a second via hole in the via layer;
forming a first metal layer;
forming a trench by etching the via layer;
forming an anode electrode on the via layer; and
forming an emission structure on the anode electrode,
wherein forming the emission structure comprises:
forming a first emission component on the anode electrode;
forming a charge generation layer on the first emission component; and
forming a second emission component on the charge generation layer,
wherein the transistor comprises an initialization transistor electrically connected to an initialization voltage node, wherein the initialization voltage node is configured to transmit an initialization voltage,
wherein forming the charge generation layer comprises contacting the charge generation layer with the first metal layer, and
wherein the charge generation layer is electrically connected to the initialization transistor.

15. The method according to claim 14, further comprising forming a partition wall on the first metal layer,
wherein forming the partition wall comprises:
forming a first partition wall layer; and
forming a second partition wall layer on the first partition wall layer, and
wherein the second partition wall layer is wider the first partition wall layer.

16. The method according to claim 15,
wherein forming the trench comprises forming a first trench and a second trench, and
wherein forming the first trench and the second trench comprises etching the via layer such that a height of the first trench is less than a height of the second trench.

17. The method according to claim 16, further comprising:
forming a second metal layer; and
forming a cathode electrode on the second emission component,
wherein the second metal layer is electrically connected to the pixel circuit layer through the second via hole,
wherein the first metal layer and the second metal layer are formed in an identical process,
wherein forming the cathode electrode comprises contacting the cathode electrode with the second metal layer, and
wherein the second metal layer is electrically connected to a line configured to supply a cathode voltage.

18. The method according to claim 17,
wherein each of the first metal layer and the second metal layer is a single layer including titanium (Ti), or multiple layers including at least one of titanium (Ti), aluminum (Al), copper (Cu), and molybdenum titanium (MoTi), and
wherein the anode electrode has a forward-tapered side surface.

19. The method according to claim 14,
wherein the first metal layer is electrically connected to the pixel circuit layer through the second via hole, and
wherein, in a plan view, an area where the charge generation layer is in contact with the first metal layer encloses at least a portion of a periphery of the anode electrode.

20. An electronic device, comprising:
a processor configured to provide input image data; and
a display device configured to display an image based on the input image data,
wherein the display device comprises:
a pixel circuit layer;
a via layer disposed on the pixel circuit layer, wherein the via layer includes a trench;
a first via hole and a second via hole passing through the via layer;
a first metal layer electrically connected to the pixel circuit layer through the first via hole;
an anode electrode disposed on the via layer;
a first emission component disposed on the anode electrode;
a charge generation layer disposed on the first emission component; and
a second emission component disposed on the charge generation layer,
wherein the pixel circuit layer comprises:
a transistor electrically connected to an initialization voltage node, wherein the initialization voltage node is configured to transmit an initialization voltage, and
wherein the transistor is electrically connected to the charge generation layer through the first metal layer.
